(19) United States
(12) Patent Application Publication
(10) Pub. No.: US 2024/0298499 A1
(43) Pub. Date: Sep. 5, 2024

(54) DISPLAY DEVICE

(71) Applicant: Samsung Display Co., LTD., Yongin-si, Gyeonggi-do (KR)

(72) Inventors: Shin Tack KANG, Yongin-si Gyeonggi-do (KR); Young Min KIM, Asan-si Chungcheongnam-do (KR); Yu Jin KIM, Hwaseong-si Gyeonggi-do (KR); Hae Il PARK, Seoul (KR)

(21) Appl. No.: 18/258,214

(22) PCT Filed: May 4, 2021
(86) PCT No.: PCT/KR2021/005609

§ 371 Date: Jun. 19, 2023

(30) Foreign Application Priority Data
Jan. 6, 2021 (KR) 10-2021-0001368

(51) Int. Cl. H10K 59/38; H10K 59/122; H10K 59/123; H10K 59/80

(52) U.S. Cl. CPC H10K 59/38; H10K 59/122; H10K 59/123; H10K 59/873

(57) ABSTRACT

A display device includes a base portion including a display area in which a first emission area and a non-emission area are defined, a first light emitting element disposed on the base portion and overlapping the first emission area, a first encapsulation layer including a first lower inorganic layer disposed on the first light emitting element and a first organic layer located on the first lower inorganic layer, and a wavelength conversion pattern disposed on the first encapsulation layer and overlapping the first light emitting element. A first opening overlapping the first emission area is defined in the first organic layer, and the wavelength conversion pattern is disposed within the first opening.

### TECHNICAL FIELD

The disclosure relates to a display device.

### BACKGROUND ART

The importance of display devices has steadily increased with the development of multimedia technology. Accordingly, various types of display devices such as a liquid crystal display (LCD) device, an organic light emitting diode (OLED) display device and the like have been developed.

Among the display devices, a self-light emitting display device includes a self-light emitting element such as an organic light emitting element. The self-light emitting element may include two opposite electrodes and a light emitting layer interposed therebetween. In the case of using the organic light emitting element as the self-light emitting element, the electrons and holes from the two electrodes are recombined in the light emitting layer to produce excitons, which transition from the excited state to the ground state, emitting light.

The self-light emitting display device is attracting attention as a next-generation display device because of being able to meet the high display quality characteristics such as wide viewing angle, high brightness and contrast, and quick response speed as well as being able to be made having a low power consumption, lightweight, and thin by not using any additional light source such as a backlight unit.

### DISCLOSURE

### Technical Problem

As one method for allowing each pixel of the display device to uniquely display one primary color, there is a method of arranging a color conversion pattern or a wavelength conversion pattern for each pixel on an optical path from a light source to a viewer.

Embodiments of the disclosure provide a display device capable of improving display quality.

It should be noted that features of embodiments the disclosure are not limited to the above-mentioned features, and other unmentioned features of embodiments of the disclosure will be clearly understood by those skilled in the art from the following descriptions.

### Technical Solution

According to embodiments of the disclosure, a display device includes: a base portion including a display area in which a first emission area and a non-emission area are defined; a first light emitting element disposed on the base portion and overlapping the first emission area; a first encapsulation layer comprising a first lower inorganic layer disposed on the first light emitting element and a first organic layer disposed on the first lower inorganic layer; and a wavelength conversion pattern disposed on the first encapsulation layer and overlapping the first light emitting element, where a first opening overlapping the first emission area is defined in the first organic layer, and the wavelength conversion pattern is disposed within the first opening.

In some embodiments, the wavelength conversion pattern may be in direct contact with the first lower inorganic layer exposed through the first opening.

In some embodiments, the display device may further include a bank pattern disposed on the first encapsulation layer and overlapping the non-emission area, the bank pattern may surround the first emission area in a plan view, and the wavelength conversion pattern may be further disposed within a space partitioned by the bank pattern.

In some embodiments, the first encapsulation layer may further include a first upper inorganic layer disposed between the bank pattern and the first organic layer, and the bank pattern may be disposed directly on the first upper inorganic layer.

In some embodiments, a second opening overlapping the first emission area may be defined in the first upper inorganic layer, and the wavelength conversion pattern may be further disposed within the second opening.

In some embodiments, the wavelength conversion pattern may be in direct contact with the first organic layer and the first upper inorganic layer.

In some embodiments, the first upper inorganic layer may be further disposed within the first opening and in direct contact with the first lower inorganic layer within the first opening.

In some embodiments, the display device may further include an insulating layer disposed on the first encapsulation layer and the bank pattern and including an inorganic material, and the insulating layer may be in direct contact with the first encapsulation layer, the wavelength conversion pattern, and the bank pattern.

In some embodiments, a portion of the insulating layer overlapping the non-emission area and disposed on the bank pattern may be spaced apart from a portion of the insulating layer overlapping the first emission area.

In some embodiments, the display device may further include a capping layer disposed on the bank pattern and the wavelength conversion pattern; and an auxiliary bank pattern disposed between the capping layer and the bank pattern and overlapping the non-emission area.

In some embodiments, the auxiliary bank pattern may be in direct contact with the wavelength conversion pattern, and at least a part of a surface of the auxiliary bank pattern may have higher liquid repellency than a surface of the bank pattern.

In some embodiments, the display device may further include a bank pattern disposed on the first encapsulation layer and overlapping the non-emission area; a capping layer disposed on the bank pattern and the wavelength conversion pattern; a color filter disposed on the capping layer, and overlapping the first emission area and the non-emission area, where the color filter may include a colorant of a first color; and a color pattern disposed on the color filter and overlapping the bank pattern and the color filter, where the color pattern includes a blue colorant different from the colorant of the first color.

In some embodiments, the display device may further include an overcoat layer disposed between the capping layer and the color filter, where a refractive index of the overcoat layer is less than a refractive index of the wavelength conversion pattern.

In some embodiments, the display device may further include a second encapsulation layer disposed on the color filter and the color pattern, where the second encapsulation layer comprises a second lower inorganic layer disposed on the color filter and the color pattern, a second organic layer disposed on the second lower inorganic layer, and a second upper inorganic layer disposed on the second organic layer.

In some embodiments, the display device may further include a second light emitting element disposed on the base portion and overlapping a second emission area which is further defined in the display area; and a light transmission pattern disposed on the first encapsulation layer and overlapping the second light emitting element, where an opening overlapping the second emission area is further defined in the first organic layer of the first encapsulation layer, and the light transmission pattern is disposed within the opening.

According to embodiments of the disclosure, a display device includes: a base portion; a switching element disposed on the base portion; an insulating layer disposed on the switching element; an anode electrode disposed on the insulating layer and electrically connected to the switching element; a pixel defining layer disposed on the insulating layer and exposing the anode electrode; a cathode electrode disposed on the pixel defining layer; a light emitting layer disposed between the cathode electrode and the anode electrode; a first lower inorganic layer disposed on the cathode electrode; a first organic layer disposed on the first lower inorganic layer, and in direct contact with the first lower inorganic layer, where an opening is defined in the first organic layer, the opening overlaps the anode electrode; a first upper inorganic layer disposed on the first organic layer and in direct contact with the first organic layer; a bank pattern disposed on the first upper inorganic layer and overlapping the pixel defining layer; a wavelength conversion pattern disposed within the opening and a space partitioned by the bank pattern, where the wavelength conversion pattern includes quantum dots; a capping layer disposed on the wavelength conversion pattern; a color filter disposed on the capping layer and overlapping the wavelength conversion pattern; and a second encapsulation layer disposed on the color filter.

In some embodiments, the display device may further include an auxiliary bank pattern disposed between the bank pattern and the capping layer, where the auxiliary bank pattern is in direct contact with the wavelength conversion pattern and the capping layer.

In some embodiments, the display device may further include an insulating layer disposed between the auxiliary bank pattern and the bank pattern, where the wavelength conversion pattern is in direct contact with the insulating layer.

In some embodiments, the bank pattern and the auxiliary bank pattern may include an organic material, and the insulating layer may include an inorganic material.

In some embodiments, the display device may further include an insulating layer disposed between the bank pattern and the capping layer, where the insulating layer is in direct contact with the capping layer, and the capping layer and the insulating layer include an inorganic material.

The details of other embodiments are included in the following description and the accompanying drawings.

### Advantageous Effects

According to embodiments of the disclosure, a display device having improved display quality and improved light efficiency may be provided.

Advantageous effects according to the disclosure are not limited to those mentioned above, and various other advantageous effects are included herein.

### DESCRIPTION OF DRAWINGS

FIG. 1 is a schematic plan view of a display device according to one embodiment.

FIG. 2 is an enlarged plan view of part Q1 of FIG. 1.

FIG. 3 is a plan view illustrating a modified embodiment of FIG. 2.

FIG. 4 is a cross-sectional view of the display device according to one embodiment taken along line X1-X1′ of FIG. 2.

FIG. 5 is an enlarged cross-sectional view of portion Q3 of FIG. 4.

FIG. 6 is a plan view illustrating a schematic arrangement of a bank pattern in a display device according to one embodiment.

FIG. 7 is a plan view illustrating a schematic arrangement of a first wavelength conversion pattern, a second wavelength conversion pattern, and a light transmission pattern in a display device according to one embodiment.

FIG. 8 is a plan view illustrating a schematic arrangement of a first color filter in a display device according to one embodiment.

FIG. 9 is a plan view illustrating a schematic arrangement of a second color filter in a display device according to one embodiment.

FIG. 10 is a plan view illustrating a schematic arrangement of a third color filter and a color pattern in a display device according to one embodiment.

FIGS. 11, 12, and 13 are views illustrating a process of forming the first and second openings of the first encapsulation layer and the bank pattern shown in FIG. 4.

FIG. 14 is a cross-sectional view illustrating a modified embodiment of the display device shown in FIG. 4.

FIG. 15 is a cross-sectional view illustrating another modified embodiment of the display device shown in FIG. 4.

FIG. 16 is a cross-sectional view illustrating still another modified embodiment of the display device shown in FIG. 4.

FIG. 17 is a cross-sectional view illustrating still another modified embodiment of the display device shown in FIG. 4.

FIG. 18 is a cross-sectional view illustrating still another modified embodiment of the display device shown in FIG. 4.

### MODES OF THE INVENTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

When an element or layer is referred to as being “on” another element or layer, it may be directly on the other element or layer or intervening elements or layers may be present. In contrast, when an element is referred to as being “directly on” another element, there are no intervening elements present. The same reference numbers indicate the same components throughout the specification.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use in addition to the orientation depicted in the figures. For example, if the device in the figures is turned over, elements described as “below” or “beneath” other elements or features would then be oriented “above” the other elements or features. Thus, the term “below” can encompass both an orientation of above and below.

Although the terms first, second, third, fourth, etc. may be used herein to describe various components, these components should not be limited by these terms. These terms are used to distinguish one component from another component. Thus, a first component discussed below could be termed any one of a second component, a third component, and a fourth component without departing from the teachings of the disclosure.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described with reference to the accompanying drawings.

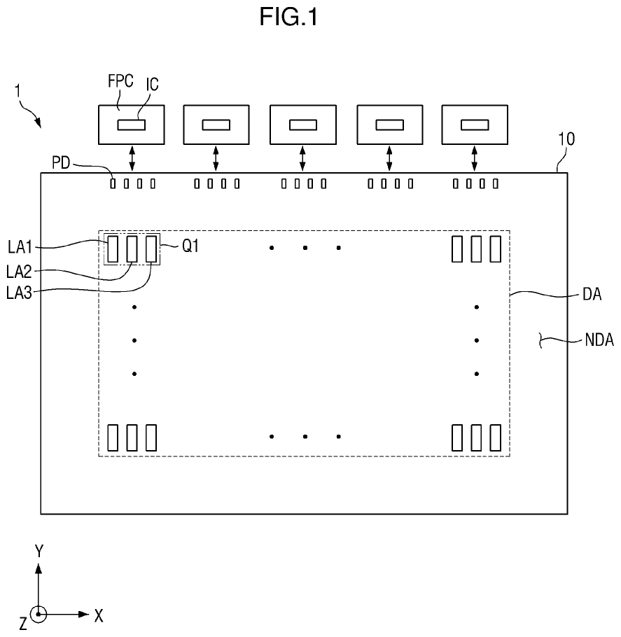

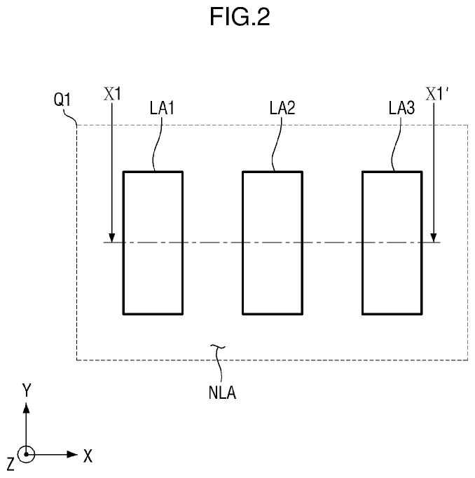

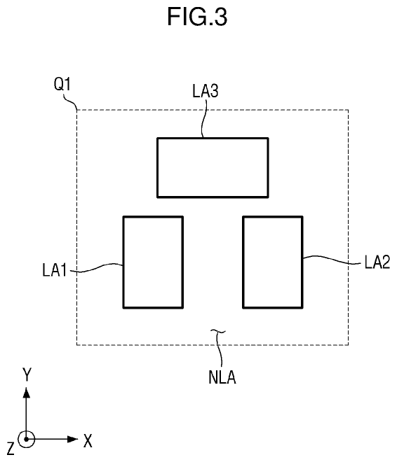

FIG. 1 is a schematic plan view of a display device according to one embodiment, FIG. 2 is an enlarged plan view of part Q1 of FIG. 1, and FIG. 3 is a plan view illustrating a modified embodiment of FIG. 2.

Referring to FIGS. 1 to 3, a display device 1 may be applied to a variety of electronic apparatuses, i.e., medium-or small-sized electronic devices such as a tablet personal computer (PC), a smartphone, a car navigation unit, a camera, a center information display (CID) provided in a vehicle, a wristwatch-type electronic device, a personal digital assistant (PDA), a portable multimedia player (PMP) and a game console, and medium and large electronic devices such as a television, an external billboard, a monitor, a personal computer and a laptop computer. These are merely suggested as examples, but the display device 1 may also be applied to other electronic devices without departing from the teachings of the disclosure.

The display device 1 may include a display panel 10. In some embodiments, the display device 1 may further include a flexible circuit board FPC and a driving chip IC.

The display panel 10 may have a rectangular shape in a plan view. The display panel 10 may include two first sides extending in a first direction X and two second sides extending in a second direction Y intersecting the first direction X. A corner where the first side and the second side of the display device 1 meet each other may have a right angle. However, the disclosure is not limited thereto, and the corner may have a curved surface. In some embodiments, the length of the first side and the length of the second side may be different from each other, but the disclosure is not limited thereto. The planar shape of the display panel 10 is not limited to the exemplified one, but may have a circular shape or other shapes.

Unless otherwise defined, the terms “above,” “upper side,” “upper portion,” “top,” and “top surface,” as used herein, refer to a direction indicated by an arrow in the drawing in a third direction Z intersecting the first and second directions X and Y based on the drawings, and the terms “below,” “lower side,” “lower portion,” “bottom,” and “bottom surface,” as used herein, refer to a direction opposite to the direction indicated by the arrow in the third direction Z based on the drawing. Here, the third direction Z may be a thickness direction of the display panel 10.

The display panel 10 may include a display area DA in which an image is displayed and a non-display area NDA in which no image is displayed.

A plurality of emission areas and a non-emission area NLA may be defined in the display area DA of the display panel 10. In some embodiments, a first emission area LA1, a second emission area LA2, and a third emission area LA3 may be defined in the display area DA of the display panel 10. In the first emission area LA1, the second emission area LA2, and the third emission area LA3, light generated from the light emitting element of the display panel 10 may be emitted to the outside of the display panel 10, and in the non-emission area NLA, light may not be emitted to the outside of the display panel 10.

The display panel 10 may include a pixel defining layer that defines the first emission area LA1, the second emission area LA2, the third emission area LA3, and the non-emission area NLA described above, a self-light emitting element, and a pixel circuit electrically connected to or electrically coupled to the self-light emitting element. In an embodiment, the self-light emitting element may include at least one of an organic light emitting diode, a quantum dot light emitting diode, an inorganic micro light emitting diode (e.g., micro LED), or an inorganic nano light emitting diode (e.g., nano LED). Hereinafter, for simplicity of description, a case where the self-light emitting element is an organic light emitting element will be described as an example.

In some embodiments, the lights emitted to the outside in the first emission area LA1, the second emission area LA2, and the third emission area LA3 may have different colors from each other. For example, light emitted from the first emission area LA1 to the outside may be light of a first color, light emitted from the second emission area LA2 may be light of a second color, and light emitted from the third emission area LA3 may be light of a third color. The light of the first color, the light of the second color, and the light of the third color may have different colors from each other.

In some embodiments, the light of the third color may be blue light having a peak wavelength in a range of about 440 nanometers (nm) to about 480 nm, and the light of the first color may be red light having a peak wavelength in a range of about 610 nm to about 650 nm. In addition, the light of the second color may be green light having a peak wavelength in a range of about 530 nm to about 570 nm. However, the disclosure is not limited thereto, and the light of the first color may be green light and the light of the second color may be red light. The light of the first color and the light of the second color may be light obtained by converting a wavelength of the light of the third color.

In some embodiments, the first emission area LA1, the second emission area LA2, and the third emission area LA3 may form one group, and a plurality of groups may be defined in the display area DA.

In some embodiments, as shown in FIG. 2, the first emission area LA1, the second emission area LA2, and the third emission area LA3 may be sequentially positioned along the first direction X. In some embodiments, in the display area DA, the first emission area LA1, the second emission area LA2, and the third emission area LA3 may form one group and be repeatedly arranged along the first direction X and the second direction Y in a matrix form.

However, the disclosure is not limited thereto, and the arrangement of the first emission area LA1, the second emission area LA2, and the third emission area LA3 may be variously changed. In an alternative embodiment, as shown in FIG. 3, the first emission area LA1 and the second emission area LA2 may be adjacent to each other along the first direction X, and the third emission area LA3 may be located at one sides of the first emission area LA1 and the second emission area LA2 along the second direction Y.

Hereinafter, a case in which the first emission area LA1, the second emission area LA2, and the third emission area LA3 are arranged as shown in FIG. 2 will be described as an example.

In some embodiments, the non-display area NDA of the display panel 10 may be located around the display area DA and may surround the display area DA.

A plurality of connection pads PD may be positioned in the non-display area NDA of the display panel 10. The connection pad PD may be electrically connected to the pixel circuit located in the display area DA through a connection wire or the like.

The flexible circuit board FPC may be connected to the connection pad PD of the display panel 10. The flexible circuit board FPC may electrically connect the display panel 10 and a circuit board that provides a signal and power for driving the display device 1 to each other.

The driving chip IC may be electrically connected to the circuit board to receive data and a signal. In some embodiments, the driving chip IC may be a data driving chip, and may receive a data control signal and image data from the circuit board and generate and output a data voltage corresponding to the image data to the display panel 10.

In some embodiments, the driving chip IC may be mounted on the flexible circuit board FPC. For example, the driving chip IC may be mounted on the flexible circuit board FPC in the form of a chip on film (COF).

A signal such as the data voltage provided from the driving chip IC, and a signal such as the power provided from the circuit board may be transmitted to the pixel circuit of the display panel 10 via the flexible circuit board FPC and the connection pad PD.

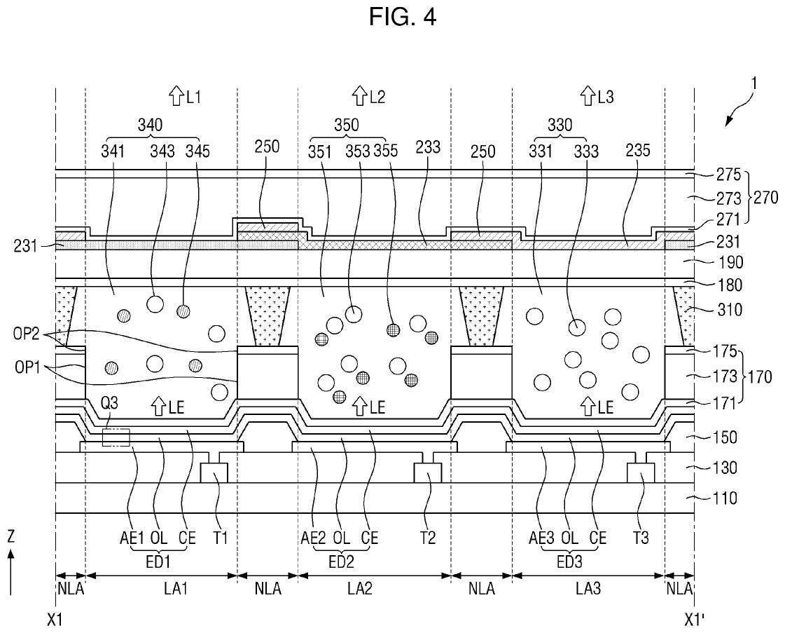

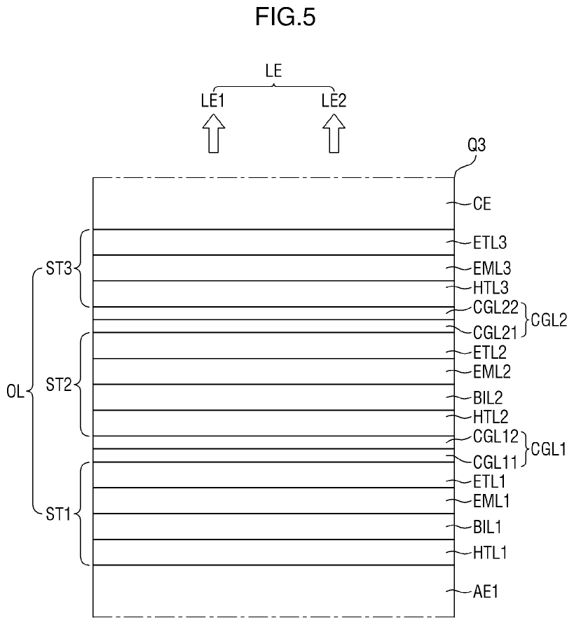

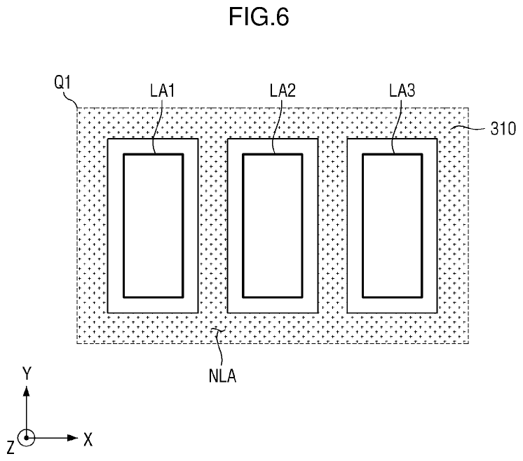

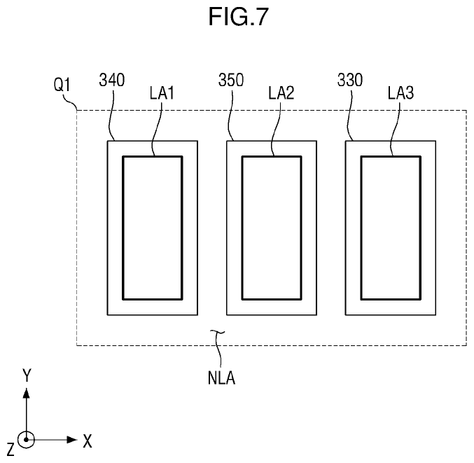

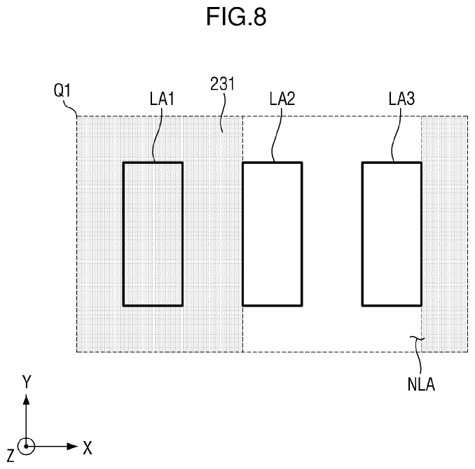

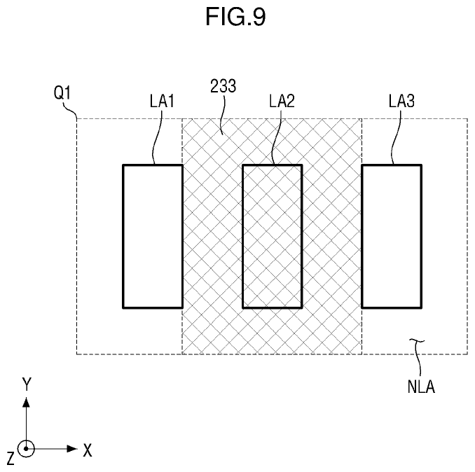

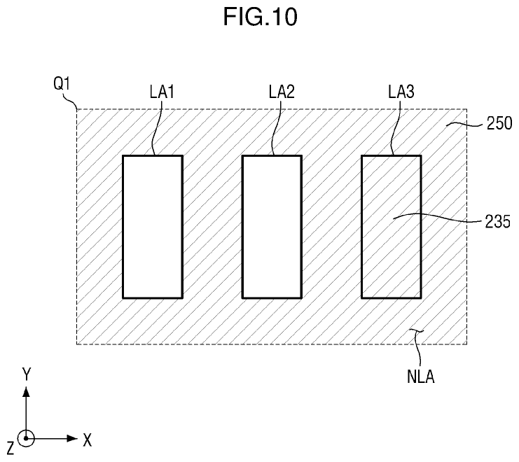

FIG. 4 is a cross-sectional view of the display device according to one embodiment taken along line X1-X1′ of FIG. 2. FIG. 5 is an enlarged cross-sectional view of portion Q3 of FIG. 4. FIG. 6 is a plan view illustrating a schematic arrangement of a bank pattern in a display device according to one embodiment. FIG. 7 is a plan view illustrating a schematic arrangement of a first wavelength conversion pattern, a second wavelength conversion pattern, and a light transmission pattern in a display device according to one embodiment. FIG. 8 is a plan view illustrating a schematic arrangement of a first color filter in a display device according to one embodiment. FIG. 9 is a plan view illustrating a schematic arrangement of a second color filter in a display device according to one embodiment. FIG. 10 is a plan view illustrating a schematic arrangement of a third color filter and a color pattern in a display device according to one embodiment.

The structure of an embodiment of the display device 1 will be described below with reference to FIGS. 4 to 10.

In an embodiment, the display device 1 includes a base portion 110. The base portion 110 may be made of a light transmissive material. It will be understood that the terms “made of” or “formed of” when used in this specification, has the same meaning as the term “including”, and specify the presence of stated material, but do not preclude the presence or addition of one or more other material. In some embodiments, the base portion 110 may be a glass substrate or a plastic substrate. In an embodiment where the base portion 110 is a plastic substrate, the base portion 110 may have flexibility.

In some embodiments, as described above, the plurality of emission areas LA1, LA2, and LA3 and the non-emission area NLA may be defined in the base portion 110.

As shown in FIG. 4, switching elements T1, T2, and T3 may be positioned (or disposed) on the base portion 110. In some embodiments, the first switching element T1 may overlap the first emission area LA1, the second switching element T2 may overlap the second emission area LA2, and the third switching element T3 may overlap the third emission area LA3. Although it is illustrated in the drawings that the first switching element T1, the second switching element T2, and the third switching element T3 do not overlap the non-emission area NLA, this is merely an example. In an alternative embodiment, at least one of the first switching element T1, the second switching element T2, or the third switching element T3 may overlap the non-emission area NLA. Alternatively, all of the first switching element T1, the second switching element T2, and the third switching element T3 may overlap the non-emission area NLA.

Although not shown in the drawings, a plurality of signal lines (e.g., gate line, data line, power line, and the like) that transmit signals to the switching elements may be further positioned on the base portion 110.

Each of the first switching element T1, the second switching element T2, and the third switching element T3 may be a thin film transistor.

An insulating layer 130 may be located on the first switching element T1, the second switching element T2 and the third switching element T3. In some embodiments, the insulating layer 130 may be a planarization layer. In some embodiments, the insulating layer 130 may include an organic material. For example, the insulating layer 130 may include acrylic resin, epoxy resin, imide resin, ester resin, or the like. In some embodiments, the insulating layer 130 may include a photosensitive organic material.

A first anode electrode AE1, a second anode electrode AE2, and a third anode electrode AE3 may be positioned on the insulating layer 130.

The first anode electrode AE1 may overlap the first emission area LA1 and may at least partially extend to the non-emission area NLA. The second anode electrode AE2 may overlap the second emission area LA2, and at least a portion thereof may extend to the non-emission area NLA. The third anode electrode AE3 may overlap the third emission area LA3, and at least a portion thereof may extend to the non-emission area NLA. The first anode electrode AE1 may be connected to the first switching element T1 through a hole defined in the insulating layer 130, and the second anode electrode AE2 may be connected to the second switching element T2 through a hole defined in the insulating layer 130. The third anode electrode AE3 may be connected to the third switching element T3 through a hole defined in the insulating layer 130.

In some embodiments, the first anode electrode AE1, the second anode electrode AE2, and the third anode electrode AE3 may be reflective electrodes. In such embodiments, the first anode electrode AE1, the second anode electrode AE2 and the third anode electrode AE3 may be a metal layer containing at least one of Ag, Mg, Al, Pt, Pd, Au, Ni, Nd, Ir, or Cr. In an alternative embodiment, the first anode electrode AE1, the second anode electrode AE2 and the third anode electrode AE3 may further include a metal oxide layer stacked on or under the metal layer. In some embodiments, the metal oxide layer may be a light-transmitting metal oxide layer. In an embodiment, the first anode electrode AE1, the second anode electrode AE2, and the third anode electrode AE3 may have a multilayer structure including a metal layer and a metal oxide layer, e.g., a two-layer structure of ITO/Ag, Ag/ITO, ITO/Mg, or ITO/MgF, or a three-layer structure such as ITO/Ag/ITO.

A pixel defining layer 150 may be positioned on the first anode electrode AE1, the second anode electrode AE2 and the third anode electrode AE3. An opening exposing the first anode electrode AE1, an opening exposing the second anode electrode AE2, and an opening exposing the third anode electrode AE3 may be defined through the pixel defining layer 150, and the pixel defining layer 150 may define the first emission area LA1, the second emission area LA2, the third emission area LA3, and the non-emission area NLA. That is, a region of the first anode electrode AE1 which is exposed without being covered by the pixel defining layer 150 may be the first emission area LA1. Similarly, a region of the second anode electrode AE2 which is exposed without being covered by the pixel defining layer 150 may be the second emission area LA2, and a region of the third anode electrode AE3 which is exposed without being covered by the pixel defining layer 150 may be the third emission area LA3. Further, a region where the pixel defining layer 150 is located may be the non-emission area NLA.

In some embodiments, the pixel defining layer 150 may include an organic insulating material including at least one selected from acrylic resin, epoxy resin, phenolic resin, polyamide resin, polyimide resin, unsaturated polyester resin, polyphenylene ether resin, polyphenylenesulfide resin and benzocyclobutene (BCB).

In some embodiments, the pixel defining layer 150 may overlap a color pattern 250 to be described later. In addition, the pixel defining layer 150 may further overlap a first color filter 231 and a second color filter 233.

In some embodiments, the pixel defining layer 150 may also overlap a bank pattern 310 to be described later.

As shown in FIG. 4, a light emitting layer OL may be positioned on the first anode electrode AE1, the second anode electrode AE2, and the third anode electrode AE3.

In some embodiments, the light emitting layer OL may have a shape of a continuous film formed over the plurality of emission areas LA1, LA2, and LA3 and the non-emission area NLA. A more detailed description of the light emitting layer OL will be given later.

As shown in FIG. 4, a cathode electrode CE may be positioned on the light emitting layer OL.

In some embodiments, the cathode electrode CE may have a semi-transmissive or transmissive property. In an embodiment where the cathode electrode CE has a semi-transmissive property, the cathode electrode CE may include Ag, Mg, Cu, Al, Pt, Pd, Au, Ni, Nd, Ir, Cr, Li, Ca, LiF/Ca, LiF/Al, Mo, Ti or a compound or mixture thereof, such as a mixture of Ag and Mg. In an embodiment, the cathode electrode CE has a thickness of tens to hundreds of angstroms, such that the cathode electrode CE may have a semi-transmissive property.

In an embodiment where the cathode electrode CE has a transmissive property, the cathode electrode CE may include a transparent conductive oxide (TCO). For example, the cathode electrode CE may include tungsten oxide (WxOx), titanium oxide (TiO₂), indium tin oxide (ITO), indium zinc oxide (IZO), zinc oxide (ZnO), indium tin zinc oxide (ITZO), magnesium oxide (MgO) or the like.

The first anode electrode AE1, the light emitting layer OL and the cathode electrode CE may constitute a first light emitting element ED1. The second anode electrode AE2, the light emitting layer OL and the cathode electrode CE may constitute a second light emitting element ED2. The third anode electrode AE3, the light emitting layer OL and the cathode electrode CE may constitute a third light emitting element ED3. Each of the first light emitting element ED1, the second light emitting element ED2, and the third light emitting element ED3 may emit emission light LE.

As shown in FIG. 5, the emission light LE finally emitted from the light emitting layer OL may be mixed light in which a first component LE1 and a second component LE2 are mixed (or combined) with each other. The first component LE1 and the second component LE2 of the emission light LE may each have a peak wavelength in a range from about 440 nm to about 480 nm, and the peak wavelengths of the first component LE1 and the second component LE2 may be selected to be the same as or different from each other. That is, the emission light LE may be blue light.

As shown in FIG. 5, in some embodiments, the light emitting layer OL may have a structure, e.g., a tandem structure, in which a plurality of light emitting layers are disposed to overlap each other. For example, the light emitting layer OL may include a first stack ST1 including a first light emitting layer EML1, a second stack ST2 positioned on the first stack ST1 and including a second light emitting layer EML2, a third stack ST3 positioned on the second stack ST2 and including a third light emitting layer EML3, a first charge generation layer CGL1 positioned between the first stack ST1 and the second stack ST2, and a second charge generation layer CGL2 positioned between the second stack ST2 and the third stack ST3. The first stack ST1, the second stack ST2, and the third stack ST3 may be disposed to overlap each other.

The first light emitting layer EML1, the second light emitting layer EML2, and the third light emitting layer EML3 may be disposed to overlap each other.

In some embodiments, all the first light emitting layer EML1, the second light emitting layer EML2, and the third light emitting layer EML3 may emit light of the first color, e.g., blue light. For example, each of the first light emitting layer EML1, the second light emitting layer EML2, and the third light emitting layer EML3 may be a blue light emitting layer, and may include an organic material. However, the disclosure is not limited thereto, and in an alternative embodiment, at least one of the first light emitting layer EML1, the second light emitting layer EML2, or the third light emitting layer EML3 may include an inorganic material that emits blue light. For example, at least one of the first light emitting layer EML1, the second light emitting layer EML2, or the third light emitting layer EML3 may be formed of (or include) an inorganic light emitting element or may be a part of an inorganic light emitting element. In some other embodiments, the inorganic light emitting element may be an inorganic light emitting element having micro-sized cross section or a nano-sized cross section.

In some embodiments, at least one of the first light emitting layer EML1, the second light emitting layer EML2, or the third light emitting layer EML3 may emit first blue light having a first peak wavelength, and at least another one thereof may emit second blue light having a second peak wavelength different from the first peak wavelength. For example, any one of the first light emitting layer EML1, the second light emitting layer EML2, and the third light emitting layer EML3 may emit the first blue light having the first peak wavelength, and the other two thereof may emit the second blue light having the second peak wavelength. That is, the emission light LE finally emitted from the light emitting layer OL may be mixed light in which the first component LE1 and the second component LE2 are mixed with each other, the first component LE1 may be the first blue light having the first peak wavelength, and the second component LE2 may be the second blue light having the second peak wavelength.

In some embodiments, one of the first peak wavelength and the second peak wavelength may be in a range of about 440 nm to about 460 nm, and the other one thereof may be in a range of about 460 nm to about 480 nm. However, the range of the first peak wavelength and the range of the second peak wavelength are not limited thereto. For example, the range of the first peak wavelength and the range of the second peak wavelength may both include about 460 nm. In some embodiments, one of the first blue light and the second blue light may be deep blue color, and the other one thereof may be sky blue color.

In accordance with some embodiments, the emission light LE emitted from the light emitting layer OL may be blue light, and may include a long wavelength component and a short wavelength component. Therefore, ultimately, the light emitting layer OL may emit blue light having an emission peak in a broader wavelength range as the emission light LE. Accordingly, there is an advantage in that color visibility may be improved at a side viewing angle compared to a conventional light emitting element emitting blue light having a sharp emission peak.

In some embodiments, each of the first light emitting layer EML1, the second light emitting layer EML2, and the third light emitting layer EML3 may include a host and a dopant. A material of the host is not particularly limited as long as it is generally used. For example, tris(8-hydroxyquinolinato)aluminium (Alq3), 4,4′-bis(N-carbazolyl)-1,1′-biphenyl (CBP), poly(n-vinylcarbazole) (PVK), 9,10-di(naphthalene-2-yl)anthracene (ADN), 4,4′,4″-Tris(carbazol-9-yl)-triphenylamine (TCTA), 1,3,5-tris(N-phenylbenzimidazole-2-yl)benzene (TPBi), 3-tert-butyl-9,10-di(naphth-2-yl)anthracene (TBADN), distyrylarylene (DSA), 4,4′-bis(9-carbazolyl)-2,2′-dimethyl-biphenyl (CDBP), or 2-methyl-9,10-bis(naphthalen-2-yl)anthracene (MADN) may be used as the material of the host.

Each of the first light emitting layer EML1, the second light emitting layer EML2, and the third light emitting layer EML3 that emits blue light may include, e.g., a fluorescent material including at least one selected from spiro-DPVBi, spiro-6P, distyryl-benzene (DSB), distyryl-arylene (DSA), polyfluorene (PFO)-based polymer, and poly(p-phenylene vinylene) (PPV)-based polymer. In an alternative embodiment, for example, a phosphorescent material containing an organometallic complex such as (4,6-F2ppy)2Irpic may be included in each of the first light emitting layer EML1, the second light emitting layer EML2, and the third light emitting layer EML3. However, the material that emits blue light is not limited thereto.

As described above, at least one of the first light emitting layer EML1, the second light emitting layer EML2, or the third light emitting layer EML3 emits blue light of a wavelength range different from that of at least another one of the first light emitting layer EML1, the second light emitting layer EML2, or the third light emitting layer EML3. In an embodiment, the first light emitting layer EML1, the second light emitting layer EML2, and the third light emitting layer EML3 may include the same material as each other, and a resonance distance thereof may be adjusted to emit blue light in different wavelength ranges from each other. Alternatively, at least one of the first light emitting layer EML1, the second light emitting layer EML2, and the third light emitting layer EML3, and at least another one of the first light emitting layer EML1, the second light emitting layer EML2, and the third light emitting layer EML3 may include different materials from each other to emit blue light in different wavelength ranges.

However, the disclosure is not limited thereto. All of the first light emitting layer EML1, the second light emitting layer EML2, and the third light emitting layer EML3 may emit blue light having a peak wavelength in a range of about 440 nm to about 480 nm, and may be made of the same material as each other.

Alternatively, at least one of the first light emitting layer EML1, the second light emitting layer EML2, or the third light emitting layer EML3 may emit first blue light having a first peak wavelength, another one thereof may emit second blue light having a second peak wavelength different from the first peak wavelength, and the remaining one thereof may emit third blue light having a third peak wavelength different from the first peak wavelength and the second peak wavelength. In some other embodiments, within a range in which the first peak wavelength, the second peak wavelength, and the third peak wavelength satisfy different conditions, any one of the first peak wavelength, the second peak wavelength, and the third peak wavelength may be in a range of about 440 nm to about 460 nm, and another one of the first peak wavelength, the second peak wavelength, and the third peak wavelength may be in a range of about 460 nm to about 470 nm, and the remaining one of the first peak wavelength, the second peak wavelength, and the third peak wavelength may be in a range of about 470 nm to about 480 nm.

According to still some other embodiments, the emission light LE emitted from the light emitting layer OL is blue light and includes a long wavelength component, an intermediate wavelength component, and a short wavelength component. Therefore, ultimately, the light emitting layer OL may emit blue light having an emission peak in a broader wavelength range as the emission light LE, thereby improving the color visibility at a side viewing angle.

In accordance with the above-described embodiments, compared to the conventional light emitting element that does not adopt a tandem structure, i.e., a structure in which a plurality of light emitting layers are stacked, it is advantageous in that the light efficiency increases and the lifespan of the display device increases. Alternatively, in still some other embodiments, at least one of the first light emitting layer EML1, the second light emitting layer EML2, or the third light emitting layer EML3 may emit light of the third color, e.g., blue light, and at least another one thereof may emit light of the second color, e.g., green light. In still some other embodiments, the peak wavelength of the blue light emitted from at least one of the first light emitting layer EML1, the second light emitting layer EML2, or the third light emitting layer EML3 may be in a range of about 440 nm to about 480 nm, or in a range of about 460 nm to about 480 nm. The green light emitted from at least another one of the first light emitting layer EML1, the second light emitting layer EML2, or the third light emitting layer EML3 may have a peak wavelength in a range of about 510 nm to about 550 nm.

For example, any one of the first light emitting layer EML1, the second light emitting layer EML2, and the third light emitting layer EML3 may be a green light emitting layer that emits green light, and the other two thereof may be blue light emitting layers that emit blue light. In an embodiment where the other two of the first light emitting layer EML1, the second light emitting layer EML2, and the third light emitting layer EML3 are the blue light emitting layers, the blue light emitted from the two blue light emitting layers may have the same peak wavelength range as each other, or may have different peak wavelength ranges from each other.

In accordance with some other embodiments, the emission light LE emitted from the light emitting layer OL may be a mixed light in which the first component LE1 that is blue light and the second component LE2 that is green light are mixed with each other. Similarly to the above-described embodiments, the emission light LE emitted from the light emitting layer OL, which is a mixture of blue light and green light, includes a long wavelength component and a short wavelength component. Therefore, ultimately, the light emitting layer OL may emit blue light having an emission peak in a broader wavelength range as the emission light LE, thereby improving the color visibility at a side viewing angle. In addition, since the second component LE2 of the emission light LE is green light, the green light component of the light provided from the display device 1 to the outside may be supplemented, thereby improving the color reproducibility of the display device 1.

The first charge generation layer CGL1 may be positioned between the first stack ST1 and the second stack ST2. The first charge generation layer CGL1 may serve to allow electric charge to be injected into each light emitting layer. The first charge generation layer CGL1 may serve to control charge balance between the first stack ST1 and the second stack ST2. The first charge generation layer CGL1 may include an n-type charge generation layer CGL11 and a p-type charge generation layer CGL12. The p-type charge generation layer CGL12 may be disposed on the n-type charge generation layer CGL11, and between the n-type charge generation layer CGL11 and the second stack ST2.

The first charge generation layer CGL1 may have a structure in which the n-type charge generation layer CGL11 and the p-type charge generation layer CGL12 are in contact with each other. The n-type charge generation layer CGL11 is disposed closer to the anode electrodes AE1, AE2 (see FIGS. 4), and AE3 (see FIG. 4) than the cathode electrode CE. The p-type charge generation layer CGL12 is disposed closer to the cathode electrode CE than the anode electrodes AE1, AE2 (see FIG. 4), and AE3 (see FIG. 4). The n-type charge generation layer CGL11 supplies electrons to the first light emitting layer EML1 adjacent to the anode electrodes AE1, AE2 (see FIGS. 4), and AE3 (see FIG. 4), and the p-type charge generation layer CGL12 supplies holes to the second light emitting layer EML2 included in the second stack ST2. The first charge generation layer CGL1 is disposed between the first stack ST1 and the second stack ST2 to provide electric charge to each light emitting layer, thereby increasing luminous efficiency and decreasing a driving voltage.

The first stack ST1 may be positioned on the first anode electrode AE1, the second anode electrode AE2 (see FIG. 4), and the third anode electrode AE3 (see FIG. 4), and may further include a first hole transport layer HTL1, a first electron block layer BIL1, and a first electron transport layer ETL1.

The first hole transport layer HTL1 may be positioned on the first anode electrode AE1, the second anode electrode AE2 (see FIG. 4), and the third anode electrode AE3 (see FIG. 4). The first hole transport layer HTL1 serves to facilitate the transport of holes and may include a hole transport material. The hole transport material may include a carbazole-based derivative such as N-phenylcarbazole and polyvinylcarbazole, a fluorene-based derivative, a triphenylamine-based derivative such as N,N′-bis(3-methylphenyl)-N,N′-diphenyl)-[1,1-biphenyl]-4,4′-diamine (TPD) and 4,4′,4″-tris(N-carbazolyl)triphenylamine (TCTA), N,N′-di(1-naphthyl)-N,N′-diphenylbenzidine (NPB), 4,4′-Cyclohexylidene bis[N,N-bis(4-methylphenyl)benzenamine] (TAPC), or the like, but the disclosure is not limited thereto.

The first electron block layer BIL1 may be positioned on the first hole transport layer HTL1, and between the first hole transport layer HTL1 and the first light emitting layer EML1. The first electron block layer BIL1 may include a hole transport material and a metal or metal compound to prevent electrons generated in the first light emitting layer EML1 from moving into the first hole transport layer HTL1. In some embodiments, the first hole transport layer HTL1 and the first electron block layer BIL1 described above may also be formed of a single layer in which respective materials are mixed.

The first electron transport layer ETL1 may be positioned on the first light emitting layer EML1, and between the first charge generation layer CGL1 and the first light emitting layer EML1. In some embodiments, the first electron transport layer ETL1 may include an electron transport material such as tris(8-hydroxyquinolinato)aluminum (Alq3), 1,3,5-tri(1-phenyl-1H-benzo[d]imidazol-2-yl)phenyl (TPBi), 2,9-dimethyl-4,7-diphenyl-1,10-phenanthroline (BCP), (4,7-diphenyl-1,10-phenanthroline (Bphen), 3-(4-Biphenylyl)-4-phenyl-5-tert-butylphenyl-1,2,4-triazole (TAZ), 4-(Naphthalen-1-yl)-3,5-diphenyl-4H-1,2,4-triazole (NTAZ), 2-(4-Biphenylyl)-5-(4-tert-butylphenyl)-1,3,4-oxadiazole (tBu-PBD), bis(2-methyl-8-quinolinolato-N1,O8)-(1,1′-Biphenyl-4-olato)aluminum (BAlq), berylliumbis(benzoquinolin-10-olate (Bebq2), 9,10-di(naphthalene-2-yl)anthracene (ADN), and a mixture thereof. However, the disclosure is not limited to the type of the electron transport material. The second stack ST2 may be positioned on the first charge generation layer CGL1, and further include a second hole transport layer HTL2, a second electron block layer BIL2, and a second electron transport layer ETL1.

The second hole transport layer HTL2 may be positioned on the first charge generation layer CGL1. The second hole transport layer HTL2 may be made of the same material as the first hole transport layer HTL1, or may include at least one selected from the materials listed above with respect to the first hole transport layer HTL1. The second hole transport layer HTL2 may be formed of (or defined by) a single layer or a plurality of layers.

The second electron block layer BIL2 may be positioned on the second hole transport layer HTL2, and between the second hole transport layer HTL2 and the first light emitting layer EML2. The second electron block layer BIL2 may be formed of the same material as and the same structure as the first electron block layer BIL1, or may include at least one selected from the materials listed above with respect to the first electron block layer BIL1.

The second electron transport layer ETL2 may be positioned on the second light emitting layer EML2, and between the second charge generation layer CGL2 and the second light emitting layer EML2. The second electron transport layer ETL2 may be formed of the same material and the same structure as the first electron transport layer ETL1, or may include at least one selected from the materials listed above with respect to the first electron transport layer ETL1. The second electron transport layer ETL2 may be formed of a single layer or a plurality of layers.

The second charge generation layer CGL2 may be positioned on the second stack ST2 and between the second stack ST2 and the third stack ST3.

The second charge generation layer CGL2 may have the same structure as the first charge generation layer CGL1 described above. For example, the second charge generation layer CGL2 may include an n-type charge generation layer CGL21 disposed closer to the second stack ST2 and a p-type charge generation layer CGL22 disposed closer to the cathode electrode CE. The p-type charge generation layer CGL22 may be disposed on the n-type charge generation layer CGL21.

The second charge generation layer CGL2 may have a structure in which the n-type charge generation layer CGL21 and the p-type charge generation layer CGL22 are in contact with each other. The first charge generation layer CGL1 and the second charge generation layer CGL2 may be made of different materials from each other, or may be made of the same material as each other.

The third stack ST3 may be positioned on the second charge generation layer CGL2, and may further include a third hole transport layer HTL3 and a third electron transport layer ETL3.

The third hole transport layer HTL3 may be positioned on the second charge generation layer CGL2. The third hole transport layer HTL3 may be made of the same material as the first hole transport layer HTL1, or may include at least one selected from the materials listed above with respect to the first hole transport layer HTL1. The third hole transport layer HTL3 may be formed of a single layer or a plurality of layers. When the third hole transport layer HTL3 is formed of a plurality of layers, each layer may include a different material from another layer.

The third electron transport layer ETL3 may be positioned on the third light emitting layer EML3, and between the cathode electrode CE and the third light emitting layer EML3. The third electron transport layer ETL3 may be formed of the same material and the same structure as the first electron transport layer ETL1, or may include at least one selected from the materials listed above with respect to the first electron transport layer ETL1. The third electron transport layer ETL3 may be formed of a single layer or a plurality of layers. When the third electron transport layer ETL3 is formed of a plurality of layers, each layer may include a different material from another layer.

Although not shown in the drawings, a hole injection layer (HIL) may be further positioned at least one of between the first stack ST1 and the first anode electrode AE1, between the second anode electrode AE2 (see FIG. 4) and the third anode electrode AE3 (see FIG. 4), between the second stack ST2 and the first charge generation layer CGL1, or between the third stack ST3 and the second charge generation layer CGL2. The hole injection layer may serve to allow holes to be more smoothly injected into the first light emitting layer EML1, the second light emitting layer EML2, and the third light emitting layer EML3. In some embodiments, the hole injection layer may be made of at least one selected from cupper phthalocyanine (CuPc), poly(3,4)-ethylenedioxythiophene (PEDOT), polyaniline (PANI), and N,N-dinaphthyl-N,N′-diphenyl benzidine (NPD), but the disclosure is not limited thereto. In some embodiments, the hole injection layer may be positioned between the first stack ST1 and the first anode electrode AE1, between the second anode electrode AE2 (see FIG. 4) and the third anode electrode AE3 (see FIG. 4), between the second stack ST2 and the first charge generation layer CGL1, and between the third stack ST3 and the second charge generation layer CGL2.

Although not shown in the drawings, an electron injection layer (EIL) may be further positioned at least one of: between the third electron transport layer ETL3 and the cathode electrode CE, between the second charge generation layer CGL2 and the second stack ST2, or between the first charge generation layer CGL1 and the first stack ST1. The electron injection layer serves to facilitate electron injection, and may be made of tris(8-hydroxyquinolino)aluminum (Alq3), PBD, TAZ, spiro-PBD, BAlq, or SAlq, but the disclosure is not limited thereto. Further, the electron injection layer may be a metal halide compound, and may include at least one selected from MgF₂, LiF, NaF, KF, RbF, CsF, FrF, LiI, NaI, KI, RbI, CsI, FrI and CaF₂, but the disclosure is not limited thereto. Further, the electron injection layer may include a lanthanum-based material such as Yb, Sm, Eu, or the like. Alternatively, the electron injection layer may include both the metal halide material and the lanthanum-based material, such as RbI:Yb, KI:Yb, or the like. In an embodiment where the electron injection layer includes both the metal halide material and the lanthanum-based material, the electron injection layer may be formed by co-deposition of the metal halide material and the lanthanum-based material. In some embodiments, the electron injection layer may be positioned between the third electron transport layer ETL3 and the cathode electrode CE, between the second charge generation layer CGL2 and the second stack ST2, and between the first charge generation layer CGL1 and the first stack ST1.

The light emitting layer OL may have a modified structure in addition to the above-described structure. For example, the light emitting layer OL may include only two stacks or may include four or more stacks.

As shown in FIG. 4, a first encapsulation layer 170 may be disposed on the cathode electrode CE. The first encapsulation layer 170 protects components positioned under the first encapsulation layer 170, such as the light emitting elements ED1, ED2, and ED3, from external foreign substances such as moisture. That is, the first encapsulation layer 170 may be a thin film encapsulation layer.

In some embodiments, the first encapsulation layer 170 may be commonly disposed in the first emission area LA1, the second emission area LA2, the third emission area LA3, and the non-emission area NLA, and the first encapsulation layer 170 may cover the cathode electrode CE.

In some embodiments, the first encapsulation layer 170 may include a first lower inorganic layer 171, a first organic layer 173, and a first upper inorganic layer 175 which are sequentially stacked on the cathode electrode CE.

In some embodiments, the first lower inorganic layer 171 may cover the first light emitting element ED1, the second light emitting element ED2, and the third light emitting element ED3 in the display area DA. In some embodiments, the first lower inorganic layer 171 may be in direct contact with the cathode electrode CE. Alternatively, an additional insulating layer (not shown) is disposed on the cathode electrode CE, and the first lower inorganic layer 171 may be in direct contact with the additional insulating layer.

The first organic layer 173 may be positioned on the first lower inorganic layer 171. In some embodiments, the first organic layer 173 may be substantially disposed on the entire surface of the first lower inorganic layer 171 in the display area DA.

A first opening OP1 overlapping the first emission area LA1, the second emission area LA2, and the third emission area LA3 may be defined in the first organic layer 173.

In some embodiments, the first opening OP1 of the first organic layer 173 may overlap the first light emitting element ED1, the second light emitting element ED2, and the third light emitting element ED3. Alternatively, the first opening OP1 of the first organic layer 173 may overlap the first anode electrode AE1 of the first light emitting element ED1, the second anode electrode AE2 of the second light emitting element ED2, and the third anode electrode AE3 of the third light emitting element ED3.

In some embodiments, portions of the first lower inorganic layer 171 overlapping the first emission area LA1, the second emission area LA2, and the third emission area LA3 may be exposed through the first opening OP1 of the first organic layer 173.

In some embodiments, the first opening OP1 of the first organic layer 173 may not overlap the non-emission area NLA. Alternatively, the first opening OP1 of the first organic layer 173 may not overlap the pixel defining layer 150.

In some embodiments, the shape of the first opening OP1 included in the first organic layer 173 in a plan view may be substantially the same as that of the first emission area LA1, the second emission area LA2, and the third emission area LA3 in a plan view shown in FIGS. 6 to 10.

The first upper inorganic layer 175 may be positioned on the first organic layer 173. The first upper inorganic layer 175 may cover the top surface of the first organic layer 173.

In some embodiments, a second opening OP2 overlapping the first emission area LA1, the second emission area LA2, and the third emission area LA3 may be defined in the first upper inorganic layer 175. In some embodiments, the second opening OP2 of the first upper inorganic layer 175 may overlap the first light emitting element ED1, the second light emitting element ED2, and the third light emitting element ED3.

In some embodiments, portions of the first lower inorganic layer 171 overlapping the first emission area LA1, the second emission area LA2, and the third emission area LA3 may be exposed through the first opening OP1 of the first organic layer 173 and the second opening OP2 of the first upper inorganic layer 175.

In some embodiments, the second opening OP2 of the first upper inorganic layer 175 may not overlap the non-emission area NLA. Alternatively, the second opening OP2 of the first upper inorganic layer 175 may not overlap the pixel defining layer 150.

In some embodiments, the shape of the second opening OP2 of the first upper inorganic layer 175 in a plan view may be substantially the same as that of the first opening OP1 in a plan view. For example, the shape of the second opening OP2 of the first upper inorganic layer 175 in a plan view may be substantially the same as that of the first emission area LA1, the second emission area LA2, and the third emission area LA3 in a plan view shown in FIGS. 6 to 10.

The first upper inorganic layer 175 may be positioned on the first organic layer 173. The first upper inorganic layer 175 may cover the top surface of the first organic layer 173.

In some embodiments, each of the first lower inorganic layer 171 and the first upper inorganic layer 175 may be formed of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride or the like.

The first lower inorganic layer 171 and the first upper inorganic layer 175 may be made of the same inorganic material as each other, but are not limited thereto, and alternatively, the first lower inorganic layer 171 and the first upper inorganic layer 175 may be made of different inorganic materials from each other.

In some embodiments, the first organic layer 173 may be formed of acrylic resin, methacrylic resin, polyisoprene, vinyl resin, epoxy resin, urethane resin, cellulose resin, perylene resin or the like.

The bank pattern 310 may be positioned on the first encapsulation layer 170. In some embodiments, the bank pattern 310 may be located or disposed directly on the first upper inorganic layer 175 and may be in direct contact with the first upper inorganic layer 175.

In some embodiments, the bank pattern 310 may be positioned in the non-emission area NLA of the display area DA, and as shown in FIG. 6, may surround the first emission area LA1, the second emission area LA2, and the third emission area LA3 in a plan view. The bank pattern 310 may partition a space in which a first wavelength conversion pattern 340, a second wavelength conversion pattern 350, and a light transmission pattern 330 are disposed.

As described above, the shape of the first emission area LA1, the second emission area LA2, and the third emission area LA3 in a plan view may be substantially the same as that of the first opening OP1 in a plan view. Accordingly, in some embodiments, the bank pattern 310 may surround the periphery of the first opening OP1 in a plan view.

In some embodiments, as shown in FIG. 6, the bank pattern 310 may be formed in one pattern that is integrally connected or integrally formed as a single unitary and indivisible part, but is not limited thereto. In an alternative embodiment, a portion of the bank pattern 310 surrounding the first emission area LA1, a portion of the bank pattern 310 surrounding the second emission area LA2, and a portion of the bank pattern 310 surrounding the third emission area LA3 may be formed of individual patterns separated from each other.

In some embodiments, as shown in FIG. 4, the cross section of the bank pattern 310 may have a shape in which the width of the bottom surface is smaller than that of the top surface, e.g., a reverse-tapered shape.

However, the disclosure is not limited thereto, and in an alternative embodiment, the cross-sectional shape of the bank pattern 310 may be formed such that the width of the top surface is substantially the same as the width of the bottom surface. Alternatively, the cross section of the bank pattern 310 may have a shape in which the width of the bottom surface is greater than that of the top surface, e.g., a tapered shape.

In an embodiment where the first wavelength conversion pattern 340, the second wavelength conversion pattern 350, and the light transmission pattern 330 are formed by a method, i.e., an inkjet printing method, of discharging an ink composition using a nozzle or the like, the bank pattern 310 may serve as a guide for stably positioning the discharged ink composition at a desired position. That is, the bank pattern 310 may function as a barrier wall.

In some embodiments, the bank pattern 310 may not overlap the second opening OP2 of the first upper inorganic layer 175 and the first opening OP1 of the first organic layer 173. Alternatively, in some embodiments, the bank pattern 310 may overlap the pixel defining layer 150.

In some embodiments, the bank pattern 310 may include an organic material having photocurability. In some embodiments, the bank pattern 310 may include an organic material having a light blocking property. In an embodiment where the bank pattern 310 has a light blocking property, it is possible to prevent intrusion of light between the emission areas adjacent to each other in the display area DA. For example, the bank pattern 310 may prevent the emission light LE emitted from the second light emitting element ED2 from being incident on the first wavelength conversion pattern 340 that overlaps the first emission area LA1. In addition, the bank pattern 310 may block or prevent external light from penetrating into components positioned therebelow in the non-emission area NLA.

The first and second openings OP1 and OP2 of the first encapsulation layer 170, and the bank pattern 310 may be formed as follows.

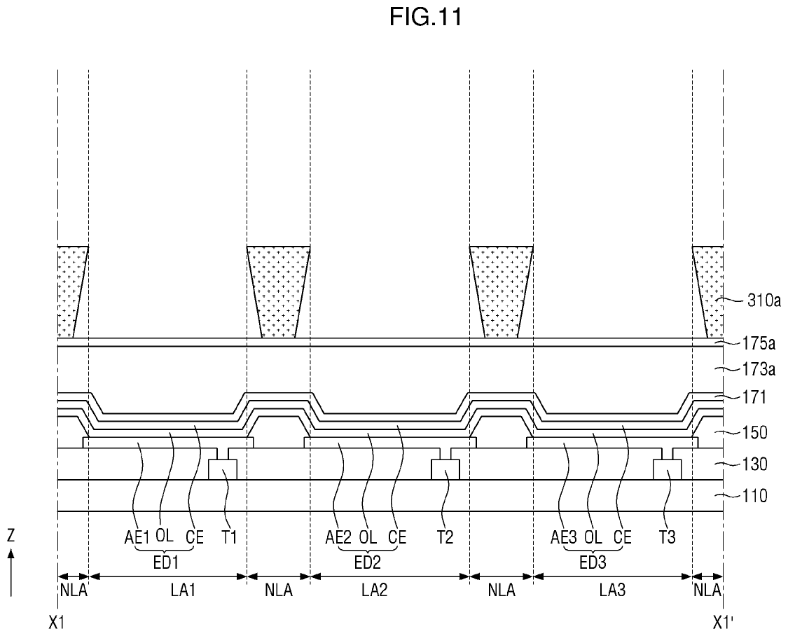

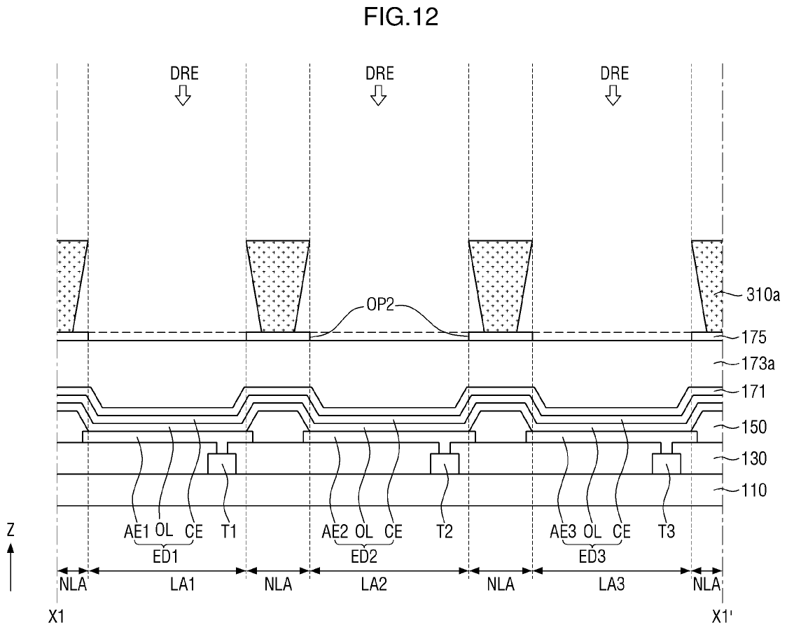

FIGS. 11, 12, and 13 are views illustrating a process of forming the first and second openings of the first encapsulation layer and the bank pattern shown in FIG. 4. Referring to FIGS. 11 to 13 in conjunction with FIG. 4, first, as shown in FIG. 11, the first lower inorganic layer 171, an unpatterned first organic layer 173a, and an unpatterned first upper inorganic layer 175 are sequentially formed on the cathode electrode CE.

Thereafter, a bank formation pattern 310a is formed on the first upper inorganic layer 175. The bank formation pattern 310a may be formed to overlap the non-emission area NLA, and may be formed, for example, by coating a photosensitive organic material on the first upper inorganic layer 175 and exposing and developing the coated photosensitive organic material.

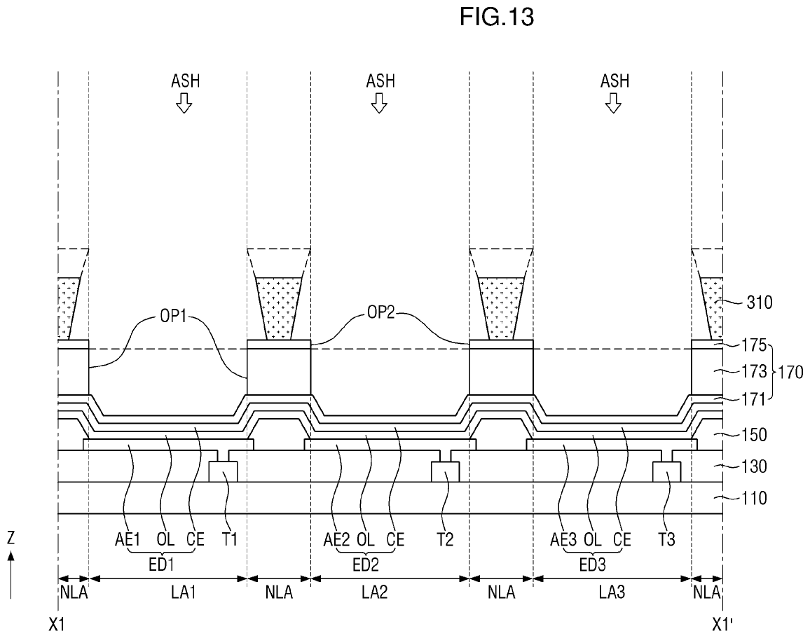

When the first upper inorganic layer 175a is patterned using the bank formation pattern 310a as a mask, as shown in FIG. 13, the first upper inorganic layer 175 having the second opening OP2 defined therein may be formed. In some embodiments, the first upper inorganic layer 175 may be formed through a dry etching process using an etching gas DRE or the like.

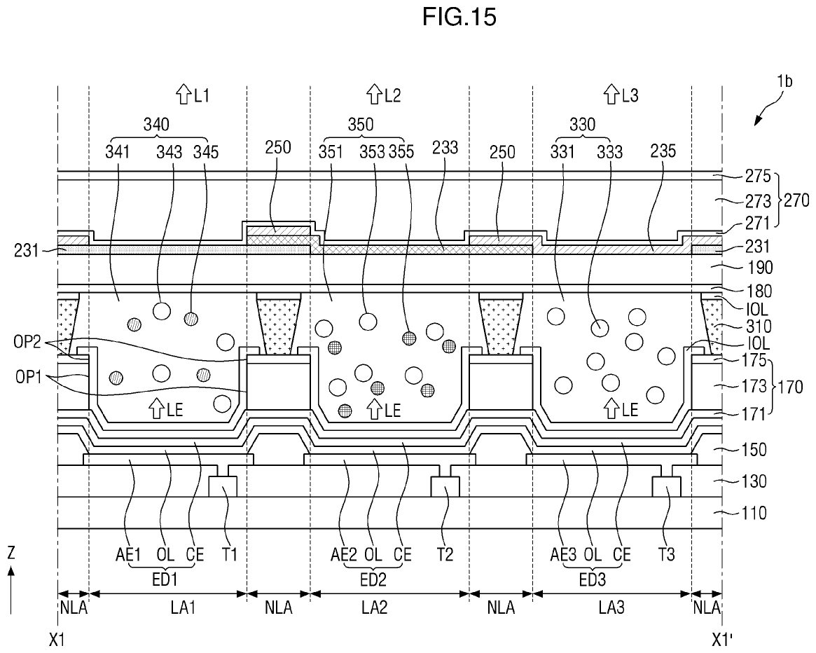

Then, when the first organic layer 173a is patterned using the bank formation pattern 310a and the first upper inorganic layer 175 as a mask, as shown in FIG. 15, the first organic layer 173 having the first opening OP1 defined therein may be formed.

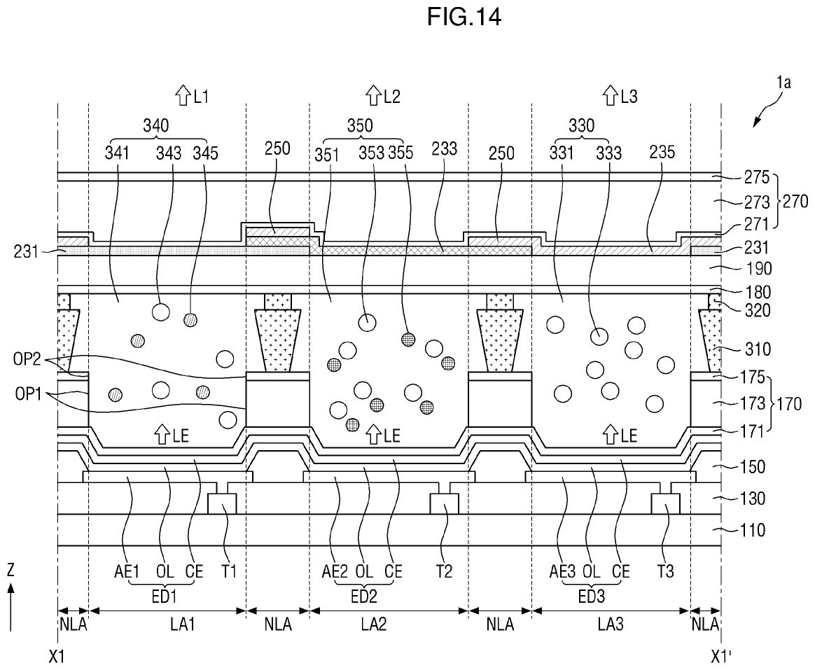

In some embodiments, the first opening OP1 of the first organic layer 173 may be formed through an ashing process using oxygen plasma ASH or the like. Since the bank formation pattern 310a shown in FIG. 14 is also made of an organic material, it may be partially removed in an ashing process, and its remaining portion may be the bank pattern 310.

Through the above process, the first encapsulation layer 170 and the bank pattern 310 may be formed.

Referring back to FIG. 4, the first wavelength conversion pattern 340, the second wavelength conversion pattern 350, and the light transmission pattern 330 may be positioned on the first encapsulation layer 170. In some embodiments, the first wavelength conversion pattern 340, the second wavelength conversion pattern 350, and the light transmission pattern 330 may be positioned in the display area DA.

The light transmission pattern 330 may overlap the third emission area LA3 or the third light emitting element ED3. The light transmission pattern 330 may be positioned within the first opening OP1 of the first organic layer 173, the second opening OP2 of the first upper inorganic layer 175, and a space partitioned by the bank pattern 310 in the third emission area LA3.

In some embodiments, the light transmission pattern 330 may be formed in an island-shaped pattern as shown in FIG. 7. In some embodiments, a part of the light transmission pattern 330 may overlap the non-emission area NLA.

The light transmission pattern 330 may transmit incident light. The emission light LE provided from the third light emitting element ED3 may be blue light as described above. The emission light LE, which is blue light, passes through the light transmission pattern 330 and the third color filter 235 and is emitted to the outside of the display device 1. That is, the third light L3 emitted from the third emission area LA3 to the outside of the display device 1 may be blue light.

In some embodiments, the light transmission pattern 330 may include a first base resin 331, and may further include a first scatterer 333 dispersed in the first base resin 331.

The first base resin 331 may be made of a material having high light transmittance. In some embodiments, the first base resin 331 may be formed of an organic material. For example, the first base resin 331 may include an organic material such as epoxy resin, acrylic resin, cardo resin, or imide resin.

The first scatterer 333 may have a refractive index different from that of the first base resin 331 and form an optical interface with the first base resin 331. For example, the first scatterer 333 may be light scattering particles. The first scatterer 333 is not particularly limited as long as it is a material capable of scattering at least a portion of the transmitted light, but may be, for example, metal oxide particles or organic particles. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), and the like. Examples of a material of the organic particles may include acrylic resin and urethane resin, and the like. The first scatterer 333 may scatter light in a random direction irrespective of the incident direction of incident light, without substantially converting the wavelength of the light passing through the light transmission pattern 330.

In some embodiments, the light transmission pattern 330 may be in direct contact with the first upper inorganic layer 175, the first organic layer 173, and the bank pattern 310.

In some embodiments, where the top surface of the first lower inorganic layer 171 is partially exposed by the first opening OP1 and the second opening OP2, the light transmission pattern 330 may also be in direct contact with the top surface of the first lower inorganic layer 171.

The first wavelength conversion pattern 340 may be positioned on the first encapsulation layer 170 and may overlap the first emission area LA1 or the first light emitting element ED1.

In some embodiments, the first wavelength conversion pattern 340 may be positioned within the first opening OP1 of the first organic layer 173, the second opening OP2 of the first upper inorganic layer 175, and a space partitioned by the bank pattern 310 in the first emission area LA1.

In some embodiments, the first wavelength conversion pattern 340 may be formed in an island-shaped pattern as shown in FIG. 7. In some embodiments, a part of the first wavelength conversion pattern 340 may overlap the non-emission area NLA.

In some embodiments, the first wavelength conversion pattern 340 may be in direct contact with the first upper inorganic layer 175, the first organic layer 173, and the bank pattern 310.

In some embodiments, where the top surface of the first lower inorganic layer 171 is partially exposed by the first opening OP1 and the second opening OP2, the first wavelength conversion pattern 340 may also be in direct contact with the top surface of the first lower inorganic layer 171.

The first wavelength conversion pattern 340 may emit light by converting or shifting the peak wavelength of incident light to another specific peak wavelength. In some embodiments, the first wavelength conversion pattern 340 may convert the emission light LE provided from the first light emitting element ED1 into red light having a peak wavelength in a range of about 610 nm to about 650 nm and may emit the red light. A more detailed description of an emission spectrum and a light absorption spectrum of the first wavelength conversion pattern 340 will be given later.

In some embodiments, the first wavelength conversion pattern 340 may include a second base resin 341 and a first wavelength shifter 345 dispersed in the second base resin 341, and may further include a second scatterer 343 dispersed in the second base resin 341.

The second base resin 341 may be made of a material having high light transmittance. In some embodiments, the second base resin 341 may be formed of an organic material. In some embodiments, the second base resin 341 may be made of the same material as the first base resin 331, or may include at least one selected from the materials listed above as the constituent materials of the first base resin 331.

The first wavelength shifter 345 may convert or shift the peak wavelength of incident light to another specific peak wavelength. In some embodiments, the first wavelength shifter 345 may convert the emission light LE of the third color, which is blue light, provided from the first light emitting element ED1 into red light having a single peak wavelength in a range of about 610 nm to about 650 nm, and may emit the red light.

Examples of the first wavelength shifter 345 may include a quantum dot, a quantum bar, a phosphor, and the like. For example, a quantum dot may be a particulate material that emits light of a specific color when an electron transitions from a conduction band to a valence band.

The quantum dot may be a semiconductor nanocrystal material. The quantum dot may have a specific band gap according to its composition and size. Thus, the quantum dot may absorb light and then emit light having an intrinsic wavelength. Examples of semiconductor nanocrystal of quantum dots may include group IV nanocrystal, group II-VI compound nanocrystal, group III-V compound nanocrystal, group IV-VI nanocrystal, a combination thereof, or the like.

The group II-VI compound may be selected from binary compounds, ternary compounds, and quaternary compounds, where the binary compounds are selected from CdSe, CdTe, ZnS, ZnSe, ZnTe, ZnO, HgS, HgSe, HgTe, MgSe, MgS and mixtures thereof, the ternary compounds are selected from InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof, and the quaternary compounds are selected HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof.

The group III-V compound may be selected from binary compounds, ternary compounds, and quaternary compounds, where the binary compounds are selected from GaN, GaP, GaAs, GaSb, AlN, AlP, AlAs, AlSb, InN, InP, InAs, InSb and mixtures thereof, the ternary compounds are selected from GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP and mixtures thereof, and the quaternary compounds are selected from GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and mixtures thereof.

The group IV-VI compound may be selected from binary compounds, ternary compounds, and quaternary compounds, where the binary compounds are selected from SnS, SnSe, SnTe, PbS, PbSe, PbTe and mixtures thereof, the ternary compounds are selected from SnSeS, SnSeTe, SnSTe, PbSeS, PbSeTe, PbSTe, SnPbS, SnPbSe, SnPbTe and mixtures thereof, and the quaternary compounds are selected from SnPbSSe, SnPbSeTe, SnPbSTe and mixtures thereof. The group IV element may be selected from Si, Ge and mixtures thereof. The group IV compound may be a binary compound selected from SiC, SiGe and mixtures thereof.

In this case, the binary compound, the tertiary compound or the quaternary compound may exist in particles at a uniform concentration, or may exist in the same particle divided into states where concentration distributions are partially different. Further, the particles may have a core/shell structure in which one quantum dot surrounds another quantum dot. An interface between the core and the shell may have a concentration gradient in which the concentration of elements in the shell decreases toward the center.

In some embodiments, the quantum dot may have a core-shell structure including a core including the nanocrystal described above and a shell surrounding the core. The shell of the quantum dot may serve as a protective layer for maintaining semiconductor characteristics by preventing chemical denaturation of the core and/or as a charging layer for giving electrophoretic characteristics to the quantum dot. The shell may be a single layer or a multilayer. An interface between the core and the shell may have a concentration gradient in which the concentration of elements in the shell decreases toward the center. Examples of the shell of the quantum dot may include a metal or non-metal oxide, a semiconductor compound, and a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO, or a tertiary compound such as MgAl₂O₄, CoFe₂O₄, NiFe₂O₄ and CoMn₂O₄, but the disclosure is not limited thereto.

In addition, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb or the like, but the disclosure is not limited thereto.

The light emitted from the first wavelength shifter 345 may have a full width of half maximum (FWHM) of the emission wavelength spectrum, which is about 45 nm or less, about 40 nm or less, or about 30 nm or less. Thus, the purity and reproducibility of colors displayed by the display device 1 can be further improved. In addition, the light emitted from the first wavelength shifter 345 may be emitted in various directions regardless of the incident direction of incident light. Accordingly, side visibility of the first color displayed in the first emission area LA1 may be improved.

Part of the emission light LE provided from the first light emitting element ED1 may pass through the first wavelength conversion pattern 340 and be emitted, without being converted into red light by the first wavelength shifter 345. A component of the emission light LE incident on the first color filter 231 without being converted by the first wavelength conversion pattern 340 may be blocked by the first color filter 231. On the other hand, the emission light LE that has converted into red light by the first wavelength conversion pattern 340 passes through the first color filter 231 and is emitted to the outside. That is, first light L1 emitted to the outside of the display device 1 from the first emission area LA1 may be red light.

The second scatterer 343 may have a refractive index different from that of the second base resin 341 and form an optical interface with the second base resin 341. For example, the second scatterer 343 may be light scattering particles. A more detailed description of the second scatterer 343 is substantially the same as or similar to the description of the first scatterer 333, and thus will be omitted.

The second wavelength conversion pattern 350 may be positioned within the first opening OP1 of the first organic layer 173, the second opening OP2 of the first upper inorganic layer 175, and a space partitioned by the bank pattern 310 in the second emission area LA2.

In some embodiments, the second wavelength conversion pattern 350 may be formed in an island-shaped pattern as shown in FIG. 7. In some embodiments, a part of the second wavelength conversion pattern 350 may overlap the non-emission area NLA.

In some embodiments, the first wavelength conversion pattern 340 may be in direct contact with the first upper inorganic layer 175, the first organic layer 173, and the bank pattern 310.

The second wavelength conversion pattern 350 may emit light by converting or shifting the peak wavelength of incident light to another specific peak wavelength. In some embodiments, the second wavelength conversion pattern 350 may convert the emission light LE provided from the second light emitting element ED2 into green light having a peak wavelength in a range of about 510 nm to about 550 nm and emit the green light.

In some embodiments, the second wavelength conversion pattern 350 may include a third base resin 351 and a second wavelength shifter 355 dispersed in the third base resin 351, and may further include a third scatterer 353 dispersed in the third base resin 351.

The third base resin 351 may be made of a material having high light transmittance. In some embodiments, the third base resin 351 may be formed of an organic material. In some embodiments, the third base resin 351 may be made of the same material as the first base resin 331, or may include at least one selected from the materials listed above as the constituent materials of the first base resin 331.

The second wavelength shifter 355 may convert or shift the peak wavelength of incident light to another specific peak wavelength. In some embodiments, the second wavelength shifter 355 may convert blue light having a peak wavelength in a range of about 440 nm to about 480 nm into green light having a peak wavelength in a range of about 510 nm to about 550 nm.

Examples of the second wavelength shifter 355 may include a quantum dot, a quantum rod, a phosphor, and the like. A more detailed description of the second wavelength shifter 355 is substantially the same as or similar to the description of the first wavelength shifter 345, and thus will be omitted.

In some embodiments, both the first wavelength shifter 345 and the second wavelength shifter 355 may be formed of quantum dots. In this case, the particle size of the quantum dots constituting the second wavelength shifter 355 may be smaller than the particle size of the quantum dots constituting the first wavelength shifter 345.

The third scatterer 353 may have a refractive index different from that of the third base resin 351 and form an optical interface with the third base resin 351. For example, the third scatterer 353 may be light scattering particles. A more detailed description of the third scatterer 353 is substantially the same as or similar to the description of the second scatterer 343, and thus will be omitted.

The emission light LE emitted from the second light emitting element ED2 may be provided to the second wavelength conversion pattern 350, and the second wavelength shifter 355 may convert the emission light LE provided from the second light emitting element ED2 into green light having a peak wavelength in a range of about 510 nm to about 550 nm and may emit the green light.

Part of the emission light LE, which is blue light, may pass through the second wavelength conversion pattern 350 without being converted into green light by the second wavelength shifter 355, and then may be blocked by the second color filter 233. On the other hand, the emission light LE that has converted into green light by the second wavelength conversion pattern 350 passes through the second color filter 233 and is emitted to the outside. Accordingly, second light L2 emitted from the second emission area LA2 to the outside of the display device 1 may be green light.

As the total amount of the first wavelength shifter 345 included in the first wavelength conversion pattern 340 and the total amount of the second wavelength shifter 355 included in the second wavelength conversion pattern 350 increase, the light conversion efficiency may increase.

In an embodiment, the first opening OP1 is formed or defined in the first organic layer 173 of the first encapsulation layer 170 and the second opening OP2 is formed in the first upper inorganic layer 175 of the first encapsulation layer 170. Therefore, since the first wavelength conversion pattern 340 and the second wavelength conversion pattern 350 may be further positioned within the first opening OP1 and the second opening OP2 of the first encapsulation layer 170 as well as the space partitioned by the bank pattern 310, the total amount of the first wavelength shifter 345 overlapping the first emission area LA1 and the total amount of the second wavelength shifter 355 overlapping the second emission area LA2 may be increased without increasing the height (or thickness) of the bank pattern 310. Accordingly, the light conversion efficiency of the display device 1 may be improved without increasing the height of the bank pattern 310.

In a case where the first opening OP1 is not formed in the first organic layer 173 and the second opening OP2 is not formed in the first upper inorganic layer 175, the emission light emitted from the light emitting element passes through the first lower inorganic layer 171, the first organic layer 173, and the first upper inorganic layer 175 to be provided to the wavelength conversion pattern. For example, in the case where the first opening OP1 and the second opening OP2 are not formed in the first encapsulation layer 170, the emission light LE provided from the first light emitting element ED1 passes through the first lower inorganic layer 171, the first organic layer 173, and the first upper inorganic layer 175 to be provided to the first wavelength conversion pattern 340.

In this case, part of the emission light LE may be absorbed by the first encapsulation layer 170 while passing through the first encapsulation layer 170. In particular, since the first organic layer 173 is made of an organic material and may be thicker than the first lower inorganic layer 171 and the first upper inorganic layer 175, the emission light LE is more likely to be absorbed by the first organic layer 173 than by the first lower inorganic layer 171 and the first upper inorganic layer 175. That is, light loss is highly likely to occur while the emission light LE passes through the first organic layer 173.

According to an embodiment of the invention, the first opening OP1 is formed or defined in the first organic layer 173, such that the emission light LE emitted from the light emitting element (e.g., the first light emitting element ED1) may be provided to the wavelength conversion pattern (e.g., the first wavelength conversion pattern 340) without passing through the first organic layer 173. Accordingly, light loss occurring in the first encapsulation layer 170 may be reduced, and the amount of light provided to the wavelength conversion pattern may be increased. Accordingly, the light efficiency of the display device 1 may be improved.

In addition, according to an embodiment of the invention, the second opening OP2 is additionally defined or formed in the first upper inorganic layer 175, such that light loss occurring in the first upper inorganic layer 175 may be reduced, and accordingly the light efficiency of the display device 1 may be further improved.

A capping layer 180 may be positioned on the light transmission pattern 330, the first wavelength conversion pattern 340, and the second wavelength conversion pattern 350. The capping layer 180 may cover the light transmission pattern 330, the first wavelength conversion pattern 340, and the second wavelength conversion pattern 350. The capping layer 180 may also be located in the non-display area NDA (see FIG. 1). In the non-display area NDA (see FIG. 1), the capping layer 180 may be in direct contact with the first encapsulation layer 170 or the first upper inorganic layer 175 of the first encapsulation layer 170, and may cover the light transmission pattern 330, the first wavelength conversion pattern 340, and the second wavelength conversion pattern 350 in the display area DA (see FIG. 1). Accordingly, the second capping layer 393 can prevent contamination or damage of the light transmission pattern 330, the first wavelength conversion pattern 340 and the second wavelength conversion pattern 350 due to infiltration of impurities such as moisture or air from the outside.

In some embodiments, the capping layer 180 may be made of an inorganic material. In some embodiments, the capping layer 180 may be made of the same material as the first lower inorganic layer 171 or the first upper inorganic layer 175, or may contain at least one of the materials listed above with respect to the first lower inorganic layer 171 and the first upper inorganic layer 175. In an embodiment where the capping layer 180 is made of an inorganic material, a portion where the capping layer 180 and the first encapsulation layer 170 are in direct contact with each other may form an inorganic-inorganic junction, and may effectively block the entry of moisture or air from the outside.

In some embodiments, the first encapsulation layer 170 and the capping layer 180 may be in direct contact with each other in the non-display area NDA (see FIG. 1).

An overcoat layer 190 may be positioned on the capping layer 180. The overcoat layer 190 may flatten the upper portions of the light transmission pattern 330, the first wavelength conversion pattern 340, and the second wavelength conversion pattern 350.

In some embodiments, the overcoat layer 190 may contain (or include) an organic material, and the organic material may be a photocurable organic material.

In some embodiments, the refractive index of the overcoat layer 190 may be less than the refractive indices of the first wavelength conversion pattern 340 and the second wavelength conversion pattern 350. For example, the refractive index of the overcoat layer 190 may be in a range of about 1.1 to about 1.3, and the refractive index of the first wavelength conversion pattern 340 and the refractive index of the second wavelength conversion pattern 350 may be greater than the refractive index of the overcoat layer 190 by about 0.3 or more. For example, the refractive index of the first wavelength conversion pattern 340 and the refractive index of the second wavelength conversion pattern 350 may be in a range of about 1.7 to about 1.9.

In some embodiments, the refractive index of the overcoat layer 190 may be less than the refractive index of the light transmission pattern 330. In some embodiments, the refractive index of the light transmission pattern 330 may be greater than the refractive index of the overcoat layer 190 by about 0.3 or more.

The overcoat layer 190 having a relatively low refractive index may reflect part of light, emitted toward the upper side of the display device 1 from the first wavelength conversion pattern 340 and the second wavelength conversion pattern 350, back to the first wavelength conversion pattern 340 and the second wavelength conversion pattern 350. That is, the overcoat layer 190 may recycle at least part of light that has passed through the first wavelength conversion pattern 340 and the second wavelength conversion pattern 350 to be incident on the overcoat layer 190, thereby increasing the amount of light converted by the first wavelength conversion pattern 340 and the second wavelength conversion pattern 350, and as a result, the light efficiency of the display device 1 may be improved.

The first color filter 231, the second color filter 233, the third color filter 235, and the color pattern 250 may be positioned on the overcoat layer 190.

The first color filter 231 may be disposed to overlap the first emission area LA1, the second color filter 233 may be disposed to overlap the second emission area LA2, and the third color filter 235 may be disposed to overlap the third emission area LA3.

In some embodiments, the first color filter 231 may block or absorb light of the third color (e.g., blue light). That is, the first color filter 231 may function as a blue light blocking filter that blocks blue light. In some embodiments, the first color filter 231 may selectively transmit light of the first color (e.g., red light) and may block or absorb light of the third color (e.g., blue light) and light of the second color (e.g., green light). For example, the first color filter 231 may be a red color filter and may include a red colorant.

The second color filter 233 may block or absorb light of the third color (e.g., blue light). That is, the second color filter 233 may also function as a blue light blocking filter. In some embodiments, the second color filter 233 may selectively transmit light of the second color (e.g., green light) and may block or absorb light of the third color (e.g., blue light) and light of the first color (e.g., red light). For example, the second color filter 233 may be a green color filter and may include a green colorant.

As shown in FIGS. 4 and 8, in some embodiments, a part of the first color filter 231 may be further positioned within the non-emission area NLA and a part of the second color filter 233 may also be further positioned within the non-emission area NLA.

In some embodiments, a part of the first color filter 231 may be further positioned in the non-emission area NLA between the first emission area LA1 and the second emission area LA2 and in the non-emission area NLA between the first emission area LA1 and the third emission area LA3.

In some embodiments, a part of the second color filter 233 may be further positioned in the non-emission area NLA between the first emission area LA1 and the second emission area LA2 and in the non-emission area NLA between the second emission area LA2 and the third emission area LA3.

In some embodiments, the first color filter 231 and the second color filter 233 may overlap each other in the non-emission area NLA between the first emission area LA1 and the second emission area LA2. An overlapping portion of the first color filter 231 and the second color filter 233 in the non-emission area NLA may function as a light blocking member to prevent transmission of light.

However, the disclosure is not limited thereto, and in an alternative embodiment, the first color filter 231 and the second color filter 233 may be positioned over the entire non-emission area NLA, and in an embodiment, the first color filter 231 and the second color filter 233 may overlap each other in the entire non-emission area NLA.

The third color filter 235 may selectively transmit light of the third color (e.g., blue light) and may block or absorb light of the first color (e.g., red light) and light of the first color (e.g., green light). In some embodiments, the third color filter 235 may be a blue color filter and may include a blue colorant such as a blue dye or a blue pigment.

The color pattern 250 may be disposed to overlap the non-emission area NLA. In some embodiments, the color pattern 250 may overlap the bank pattern 310. In some embodiments, the color pattern 250 may be disposed over the entire non-emission area NLA.

The color pattern 250 may absorb part of light entering the display device 1 from the outside of the display device 1 to reduce reflected light caused by external light. A significant portion of the external light is reflected, causing a problem of distorting the color reproducibility of the display device 1. In an embodiment, the color pattern 250 is located in the non-emission area NLA, such that color distortion due to reflection of external light may be reduced.

In some embodiments, the color pattern 250 may include a blue colorant such as blue dye or blue pigment. In some embodiments, the color pattern 250 may be made of the same material as the third color filter 235 and may be formed simultaneously during the formation of the third color filter 235. In an embodiment where the color pattern 250 includes a blue colorant, external light or reflected light that has passed through the color pattern 250 has a blue wavelength band. The eye color sensibility perceived by a user's eyes depends on the color of the light. More specifically, light in the blue wavelength band may be perceived as less sensitive to the user than light in a green wavelength band and light in a red wavelength band. Therefore, as the color pattern 250 includes a blue colorant, the user may perceive the reflected light relatively less sensitively.

In some embodiments, the color pattern 250 may overlap the first color filter 231 and the second color filter 233 in the non-emission area NLA.

An overlapping portion of the first color filter 231 and the color pattern 250 and an overlapping portion of the second color filter 233 and the color pattern 250 in the non-emission area NLA may function as a light blocking member. The overlapping portion of the first color filter 231 and the color pattern 250 and the overlapping portion of the second color filter 233 and the color pattern 250 in the non-emission area NLA may absorb at least part of external light, thereby reducing color distortion due to external light reflection. In addition, it is possible to prevent light emitted to the outside from infiltrating between adjacent emission areas and causing color mixing, and accordingly, the color reproducibility of the display device 1 may be further improved.

In some embodiments, the color pattern 250 may be located relatively farther from the base portion 110 than the first color filter 231 and the second color filter 233.

A second encapsulation layer 270 may be positioned on the first color filter 231, the second color filter 233, the third color filter 235, and the color pattern 250. The second encapsulation layer 270 protects components disposed under the second encapsulation layer 270 from external foreign substances such as moisture.

The second encapsulation layer 270 is commonly disposed in the first emission area LA1, the second emission area LA2, the third emission area LA3, and the non-emission area NLA. In some embodiments, the second encapsulation layer 270 may directly cover the first color filter 231, the second color filter 233, the third color filter 235, and the color pattern 250 in the display area DA.

In some embodiments, the second encapsulation layer 270 may include a second lower inorganic layer 271, a second organic layer 273, and a second upper inorganic layer 275 which are sequentially stacked.

In some embodiments, the second lower inorganic layer 271 may directly cover the first color filter 231, the second color filter 233, the third color filter 235, and the color pattern 250 in the display area DA.

The second organic layer 273 may be positioned on the second lower inorganic layer 271. In some embodiments, an opening overlapping the first emission area LA1, the second emission area LA2, and the third emission area LA3 may not be defined in the second organic layer 273. In some embodiments, the second organic layer 273 may be positioned over the entire display area DA.

The second upper inorganic layer 275 may be positioned on the second organic layer 273. The second upper inorganic layer 275 may cover the second organic layer 273. In some embodiments, the second upper inorganic layer 275 may be in direct contact with the second lower inorganic layer 271 in the non-display area NDA (see FIG. 1) to form an inorganic-inorganic junction.

In some embodiments, the second lower inorganic layer 271 and the second upper inorganic layer 275 may be made of an inorganic insulating material. In some embodiments, the second lower inorganic layer 271 and the second upper inorganic layer 275 may be made of the same material as the first lower inorganic layer 171, or may contain at least one selected from the materials listed above as a constituent material of the first lower inorganic layer 171.

The second organic layer 273 may be positioned between the second lower inorganic layer 271 and the second upper inorganic layer 275. The second organic layer 273 may be made of an organic insulating material. In some embodiments, the second organic layer 273 may be made of the same material as the first organic layer 173 or may contain at least one selected from the materials listed above as a constituent material of the first organic layer 173.

In the display device according to the above-described embodiment, the light efficiency may be increased by reducing the distance between the wavelength conversion member and the light emitting element. In addition, since the total amount of the wavelength shifter overlapping the light emitting element can be increased without increasing the thickness of the display device, the light conversion efficiency may be improved.

FIG. 14 is a cross-sectional view illustrating a modified embodiment of the display device shown in FIG. 4.

The embodiment of the display device 1a shown in FIG. 14 is substantially the same as the embodiment shown in FIG. 4 except that the display device 1a further includes an auxiliary bank pattern 320. The same or like elements shown in FIG. 14 have been labeled with the same reference characters as used above to describe the embodiment of the display device shown in FIG. 4, and any repetitive detailed description thereof will hereinafter be omitted or simplified.

In an embodiment, as shown in FIG. 14, the auxiliary bank pattern 320 may be positioned in the non-emission area NLA. The auxiliary bank pattern 320 may be positioned on the bank pattern 310 and may overlap the color pattern 250 and the pixel defining layer 150.

In some embodiments, the auxiliary bank pattern 320 may be located directly on the bank pattern 310 and may be in direct contact with the capping layer 180.

In some embodiments, the cross-sectional shape of the auxiliary bank pattern 320 may be different from that of the bank pattern 310. For example, the cross section of the bank pattern 310 may have a reverse tapered shape, and the cross section of the auxiliary bank pattern 320 may have a shape, such as a tapered shape, a columnar shape, or a polygonal shape, different from the reverse tapered shape.

The first wavelength conversion pattern 340, the second wavelength conversion pattern 350, and the light transmission pattern 330 may be positioned in a space between the capping layer 180, the bank pattern 310, and the auxiliary bank pattern 320, and in the first opening OP1 and the second opening OP2, for each emission area.

In some embodiments, the auxiliary bank pattern 320 may be in contact with the first wavelength conversion pattern 340, the second wavelength conversion pattern 350, and the light transmission pattern 330.

In some embodiments, the auxiliary bank pattern 320 may be made of an organic material. For example, the auxiliary bank pattern 320 may be made of a photosensitive organic material. In some embodiments, the auxiliary bank pattern 320 may be made of the same material as the bank pattern 310 and may include a light blocking material.

In some embodiments, a part of the surface of the auxiliary bank pattern 320 may have higher liquid repellency than the surface of the bank pattern 310. For example, the surface of the bank pattern 310 may have more lyophilicity than a part of the surface of the auxiliary bank pattern 320 and may have relatively good wettability with respect to ink. In addition, a part of the surface of the auxiliary bank patterns 320 may have relatively worse wettability with respect to ink than the surface of the bank pattern 310.

In some embodiments, lyophilicity and liquid repellency may be defined with a contact angle of an ink to the surface. For example, if the contact angle of the ink to the surface is equal to or less than about 10 degrees, it may be defined as having lyophilicity, and if the contact angle of the ink to the surface is equal to or greater than about 35 degrees, it may be defined as having liquid repellency. For example, the contact angle between the ink and the surface of the bank pattern 310 may be equal to or less than about 10 degrees, and the contact angle between the ink and a part of the surface of the auxiliary bank pattern 320 may be equal to or greater than about 35 degrees.

In some embodiments, the top surface of the auxiliary bank pattern 320 may have liquid repellency compared to the surface of the bank pattern 310.

As described above, the first wavelength conversion pattern 340, the second wavelength conversion pattern 350, and the like may be formed by an inkjet printing method. In such an embodiment, the surface of the auxiliary bank pattern 320, e.g., the top surface of the auxiliary bank pattern 320 has liquid repellency, such that the ink composition may be stably accommodated within a region defined by the bank pattern 310 and the auxiliary bank pattern 320.

There may be limitations in manufacturing process in increasing the height of the bank pattern 310. According to an embodiment, since the auxiliary bank pattern 320 is further disposed on the bank pattern 310, such that a space for accommodating the ink composition may be increased during the manufacturing process of the wavelength conversion pattern and the like. Therefore, the thickness of the wavelength conversion pattern overlapping each emission area may be increased. Accordingly, the total amount of wavelength shifter overlapping each emission area may be further increased, and as a result, the light conversion efficiency of the display device may be improved. In addition, since the surface of the auxiliary bank pattern 320 may have higher liquid repellency than the surface of the bank pattern 310, overflow of the ink composition may be prevented during the manufacturing process of the wavelength conversion pattern, the light transmission pattern, and the like, and the wavelength conversion pattern and the light transmission pattern may be stably formed.

FIG. 15 is a cross-sectional view illustrating another modified embodiment of the display device shown in FIG. 4.

The embodiment of the display device 1b shown in FIG. 15 is substantially the same as the embodiment shown in FIG. 4 except that the display device 1b further includes an insulating layer IOL. The same or like elements shown in FIG. 15 have been labeled with the same reference characters as used above to describe the embodiment of the display device shown in FIG. 4, and any repetitive detailed description thereof will hereinafter be omitted or simplified.

In an embodiment, as shown in FIG. 15, the insulating layer IOL may be further positioned on the first encapsulation layer 170.

In some embodiments, the insulating layer IOL may be in direct contact with the first encapsulation layer 170 and the bank pattern 310. In addition, the insulating layer IOL may be in direct contact with at least one or all of the first wavelength conversion pattern 340, the second wavelength conversion pattern 350, and the light transmission pattern 330.

In some embodiments, the insulating layer IOL may include a portion disposed on the bank pattern 310 and a portion disposed on the first upper inorganic layer 175. In some embodiments, when the bank pattern 310 is formed in a shape in which the width of the bottom surface is smaller than the width of the top surface, i.e., in a reverse tapered shape, as shown in FIG. 15, a portion of the insulating layer IOL disposed on the bank pattern 310 and a portion of the insulating layer IOL disposed on the first upper inorganic layer 175 may be separated or spaced apart from each other.

In some embodiments, the insulating layer IOL may be made of an inorganic material. For example, the insulating layer IOL may contain an inorganic material such as silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride, or the like.

In some embodiments, a part of the insulating layer IOL may cover the side surface of the first organic layer 173 defining the first opening OP1 in each emission area.

The capping layer 180 may be positioned on a portion of the insulating layer IOL disposed on the bank pattern 310, and may be in direct contact with the insulating layer IOL.

According to an embodiment, the side surface or inner surface of the first organic layer 173 defining the first opening OP1 may be covered by the insulating layer IOL containing an inorganic material. Accordingly, permeation of external moisture or oxygen into the wavelength conversion pattern or the like through the first organic layer 173 may be more effectively blocked, and thus the reliability of the display device 1 may be improved.

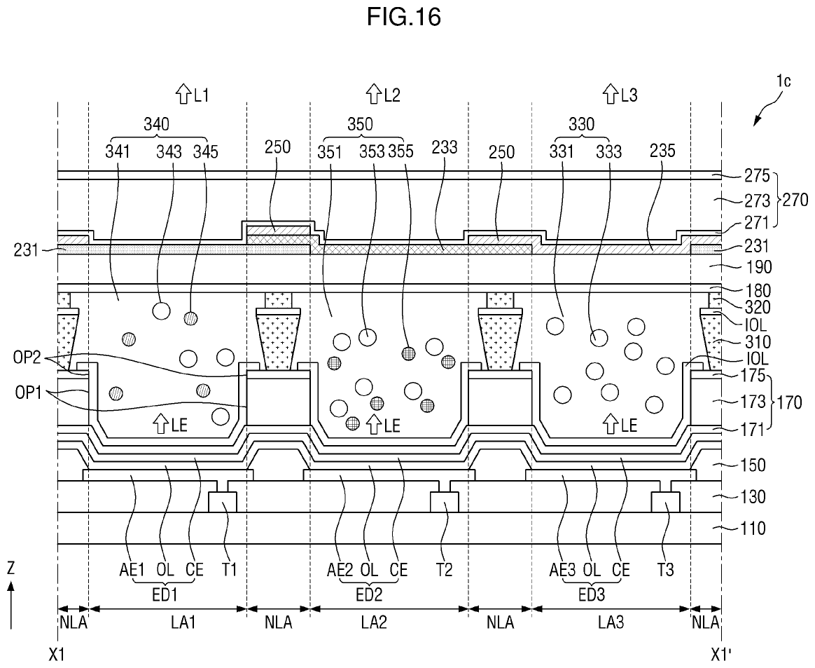

FIG. 16 is a cross-sectional view illustrating still another modified embodiment of the display device shown in FIG. 4.

The embodiment of the display device 1c shown in FIG. 16 is substantially the same as the embodiment shown in FIG. 4 except that the display device 1c further includes an insulating layer IOL and an auxiliary bank pattern 320. The same or like elements shown in FIG. 16 have been labeled with the same reference characters as used above to describe the embodiment of the display device shown in FIG. 4, and any repetitive detailed description thereof will hereinafter be omitted or simplified.

The insulating layer IOL is the same as or similar to that described above with reference to FIG. 15, and any repetitive detailed description thereof will be omitted.

The auxiliary bank pattern 320 may be positioned on a portion of the insulating layer IOL disposed on the bank pattern 310. In some embodiments, the auxiliary bank pattern 320 may be in direct contact with the insulating layer IOL. The auxiliary bank pattern 320 is the same as or similar to that described above with reference to FIG. 14, and any repetitive detailed description thereof will be omitted.

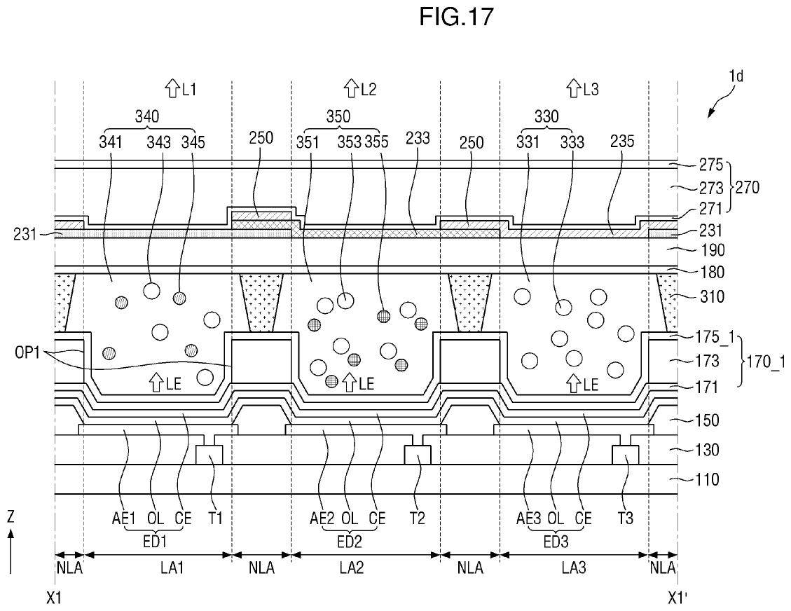

FIG. 17 is a cross-sectional view illustrating still another modified embodiment of the display device shown in FIG. 4.

The embodiment of the display device 1d shown in FIG. 17 is substantially the same as the embodiment shown in FIG. 4 except for a first encapsulation layer 170_1. The same or like elements shown in FIG. 17 have been labeled with the same reference characters as used above to describe the embodiment of the display device shown in FIG. 4, and any repetitive detailed description thereof will hereinafter be omitted or simplified.

In an embodiment, as shown in FIG. 17, the first encapsulation layer 170 includes the first lower inorganic layer 171, the first organic layer 173, and a first upper inorganic layer 175_1.

The first lower inorganic layer 171 and the first organic layer 173 are the same as those described above with reference to FIGS. 4 to 13, and any repetitive detailed description thereof will be omitted.

The first upper inorganic layer 175_1 may be positioned on the first organic layer 173 and may cover the first organic layer 173. In some embodiments, the first upper inorganic layer 175_1 may completely cover the inner side surface of the first organic layer 173 defining the first opening OP1.

In some embodiments, an opening may not be defined in the first upper inorganic layer 175_1 in the first emission area LA1, the second emission area LA2, and the third emission area LA3. The first upper inorganic layer 175_1 may also be positioned within the first opening OP1 in the first emission area LA1, the second emission area LA2, and the third emission area LA3, and may be in direct contact with the first lower inorganic layer 171 exposed in the first opening OP1.

In some embodiments, the first encapsulation layer 170 may be formed through a process of forming the first lower inorganic layer 171 on the cathode electrode CE, forming the first organic layer 173 with the first opening OP1 defined therein on the first lower inorganic layer 171, and forming the first upper inorganic layer 175 on the first organic layer 173 with the first opening OP1 defined therein.

According to an embodiment, the first upper inorganic layer 175 may completely cover the top surface of the first organic layer 173 and the side surface or inner surface of the first organic layer 173 defining the first opening OP1 in the first emission area LA1, the second emission area LA2, and the third emission area LA3. Accordingly, permeation of external moisture or oxygen into the wavelength conversion pattern or the like through the first organic layer 173 may be more effectively blocked.

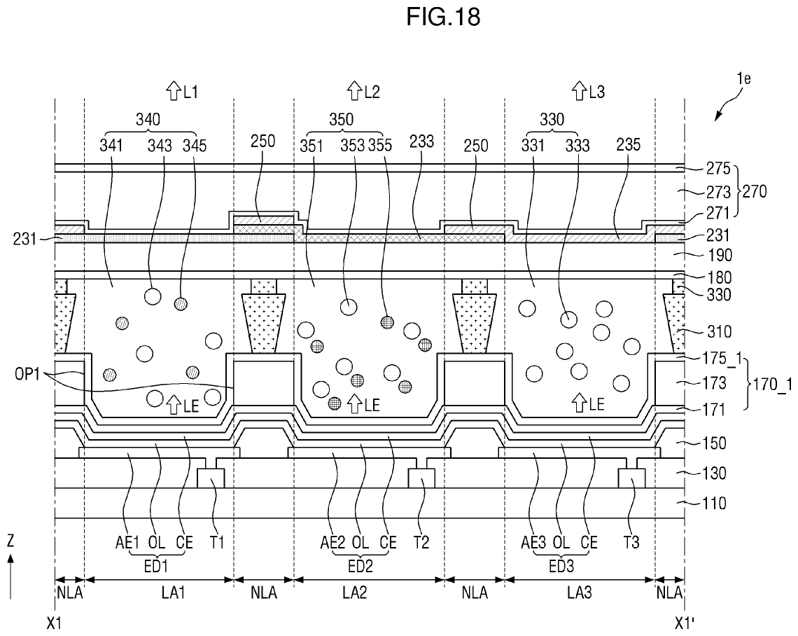

FIG. 18 is a cross-sectional view illustrating still another modified embodiment of the display device shown in FIG. 4.

The embodiment of the display device le shown in FIG. 14 is substantially the same as the embodiment shown in FIG. 4 except that the display device le further includes a first encapsulation layer 170_1 and an auxiliary bank pattern 320. The same or like elements shown in FIG. 18 have been labeled with the same reference characters as used above to describe the embodiment of the display device shown in FIG. 4, and any repetitive detailed description thereof will hereinafter be omitted or simplified.

The first encapsulation layer 170_1 is the same as or similar to that described above with reference to FIG. 17, and any repetitive detailed description thereof will be omitted.

In an embodiment, as shown in FIG. 18, the auxiliary bank pattern 320 may be positioned on the bank pattern 310. The auxiliary bank pattern 320 is substantially the same as or similar to that described above in the embodiment of FIG. 14, and any repetitive detailed description thereof will be omitted.

Although not shown in the drawings, the structure of the display device may be variously modified in addition to the above-described embodiments. For example, the first opening OP1 defined in the first organic layer 173 may be formed by removing only a part of the first organic layer 173, not an entire portion of the first organic layer 173. For example, in the above-described embodiment, it has been described that the first opening OP1 is formed in the shape of a hole as an example, but the first opening OP1 may be formed in the shape of a groove. In addition, the first lower inorganic layer 171 may not be exposed through the first opening OP1, and the first organic layer 173 may partially remain in a portion of the first lower inorganic layer 171 overlapping the first emission area LA1, the second emission area LA2, and the third emission area LA3.

In concluding the detailed description, those skilled in the art will appreciate that many variations and modifications can be made to the embodiments set forth herein without substantially departing from the principles of the disclosure. Therefore, the disclosed embodiments of the invention are used in a generic and descriptive sense only and not for purposes of limitation.

1. A display device comprising:
a base portion including a display area in which a first emission area and a non-emission area are defined;
a first light emitting element disposed on the base portion and overlapping the first emission area;
a first encapsulation layer comprising a first lower inorganic layer disposed on the first light emitting element and a first organic layer disposed on the first lower inorganic layer; and
a wavelength conversion pattern disposed on the first encapsulation layer and overlapping the first light emitting element,
wherein a first opening overlapping the first emission area is defined in the first organic layer, and
wherein the wavelength conversion pattern is disposed within the first opening.

2. The display device of claim 1, wherein the wavelength conversion pattern is in direct contact with the first lower inorganic layer exposed through the first opening.

3. The display device of claim 1, further comprising a bank pattern disposed on the first encapsulation layer and overlapping the non-emission area,
wherein the bank pattern surrounds the first emission area in a plan view, and
wherein the wavelength conversion pattern is further disposed within a space partitioned by the bank pattern.

4. The display device of claim 3, wherein the first encapsulation layer further comprises a first upper inorganic layer disposed between the bank pattern and the first organic layer, and
wherein the bank pattern is disposed directly on the first upper inorganic layer.

5. The display device of claim 4, wherein a second opening overlapping the first emission area is defined in the first upper inorganic layer, and
wherein the wavelength conversion pattern is further disposed within the second opening.

6. The display device of claim 5, wherein the wavelength conversion pattern is in direct contact with the first organic layer and the first upper inorganic layer.

7. The display device of claim 4, wherein the first upper inorganic layer is further disposed within the first opening and in direct contact with the first lower inorganic layer within the first opening.

8. The display device of claim 4, further comprising an insulating layer disposed on the first encapsulation layer and the bank pattern and containing an inorganic material,
wherein the insulating layer is in direct contact with the first encapsulation layer, the wavelength conversion pattern, and the bank pattern.

9. The display device of claim 8, wherein a portion of the insulating layer overlapping the non-emission area and disposed on the bank pattern is spaced apart from a portion of the insulating layer overlapping the first emission area.

10. The display device of claim 3, further comprising:
a capping layer disposed on the bank pattern and the wavelength conversion pattern; and
an auxiliary bank pattern disposed between the capping layer and the bank pattern and overlapping the non-emission area.

11. The display device of claim 10, wherein the auxiliary bank pattern is in direct contact with the wavelength conversion pattern, and
wherein at least a part of a surface of the auxiliary bank pattern has higher liquid repellency than a surface of the bank pattern.

12. The display device of claim 1, further comprising:
a bank pattern disposed on the first encapsulation layer and overlapping the non-emission area;
a capping layer disposed on the bank pattern and the wavelength conversion pattern;
a color filter disposed on the capping layer, and overlapping the first emission area and the non-emission area, wherein the color filter comprises a colorant of a first color; and
a color pattern disposed on the color filter and overlapping the bank pattern and the color filter,
wherein the color pattern includes a blue colorant different from the colorant of the first color.

13. The display device of claim 12, further comprising:
an overcoat layer disposed between the capping layer and the color filter,
wherein a refractive index of the overcoat layer is less than a refractive index of the wavelength conversion pattern.

14. The display device of claim 12, further comprising:
a second encapsulation layer disposed on the color filter and the color pattern,
wherein the second encapsulation layer comprises a second lower inorganic layer disposed on the color filter and the color pattern, a second organic layer disposed on the second lower inorganic layer, and a second upper inorganic layer disposed on the second organic layer.

15. The display device of claim 1, further comprising:
a second light emitting element disposed on the base portion and overlapping a second emission area which is further defined in the display area; and
a light transmission pattern disposed on the first encapsulation layer and overlapping the second light emitting element,
wherein an opening overlapping the second emission area is further defined in the first organic layer of the first encapsulation layer, and
wherein the light transmission pattern is disposed within the opening.

16. A display device comprising:
a base portion;
a switching element disposed on the base portion;
an insulating layer disposed on the switching element;
an anode electrode disposed on the insulating layer and electrically connected to the switching element;
a pixel defining layer disposed on the insulating layer and exposing the anode electrode;
a cathode electrode disposed on the pixel defining layer;
a light emitting layer disposed between the cathode electrode and the anode electrode;
a first lower inorganic layer disposed on the cathode electrode;
a first organic layer disposed on the first lower inorganic layer, and in direct contact with the first lower inorganic layer, wherein an opening is defined in the first organic layer, and the opening overlaps the anode electrode;
a first upper inorganic layer disposed on the first organic layer and in direct contact with the first organic layer;
a bank pattern disposed on the first upper inorganic layer and overlapping the pixel defining layer;
a wavelength conversion pattern disposed within the opening and a space partitioned by the bank pattern, wherein the wavelength conversion pattern comprises quantum dots;
a capping layer disposed on the wavelength conversion pattern;
a color filter disposed on the capping layer and overlapping the wavelength conversion pattern; and
a second encapsulation layer disposed on the color filter.

17. The display device of claim 16, further comprising an auxiliary bank pattern disposed between the bank pattern and the capping layer,
wherein the auxiliary bank pattern is in direct contact with the wavelength conversion pattern and the capping layer.

18. The display device of claim 17, further comprising an insulating layer disposed between the auxiliary bank pattern and the bank pattern,
wherein the wavelength conversion pattern is in direct contact with the insulating layer.

19. The display device of claim 18, wherein the bank pattern and the auxiliary bank pattern include an organic material, and
wherein the insulating layer includes an inorganic material.

20. The display device of claim 16, further comprising an insulating layer disposed between the bank pattern and the capping layer,
wherein the insulating layer is in direct contact with the capping layer, and
wherein the capping layer and the insulating layer include an inorganic material.
